(19) United States
(12) Patent Application Publication
(10) Pub. No.: US 2025/0301851 A1
(43) Pub. Date: Sep. 25, 2025

(54) ORGANIC MOLECULAR MEMORY

(71) Applicant: Kioxia Corporation, Tokyo (JP)

(72) Inventors: Kenji NAKAMURA, Yokohama Kanagawa (JP); Hideyuki NISHIZAWA, Toshima Tokyo (JP)

(21) Appl. No.: 19/064,560

(22) Filed: Feb. 26, 2025

(30) Foreign Application Priority Data
Mar. 22, 2024 (JP) 2024-046151

(51) Int. Cl. H10K 10/00; G11C 13/00; H10K 10/50; H10K 85/20; H10K 85/30

(52) U.S. Cl. CPC H10K 10/701; G11C 13/0014; G11C 13/0069; H10K 10/50; H10K 85/215; H10K 85/311; G11C 2013/009

(57) ABSTRACT

An organic molecular memory includes a first electrode, a second electrode above the first electrode in a first direction, an organic molecule layer between the first and second electrodes and including a first molecule and a second molecule, the second molecule being closer to the second electrode than the first molecule, and a third electrode facing the second molecule. Each of the first and second molecules includes a metal complex or a fullerene derivative.

### CROSS-REFERENCE TO RELATED APPLICATION

This application is based upon and claims the benefit of priority from Japanese Patent Application No. 2024-046151, filed Mar. 22, 2024, the entire contents of which are incorporated herein by reference.

### FIELD

Embodiments described herein relate generally to an organic molecular memory.

### BACKGROUND

For example, a micro-sized memory cell and a three-dimensional structure of a memory cell array are developed in order to implement a large capacity of a non-volatile memory. Implementation of a further large capacity of the non-volatile memory is desired.

### BRIEF DESCRIPTION OF THE DRAWINGS

FIG. 1 is a block diagram of an organic molecular memory according to a first embodiment.

FIG. 2 is an equivalent circuit diagram of a memory cell array of the organic molecular memory according to the first embodiment.

FIG. 3 is a schematic cross-sectional view of the organic molecular memory according to the first embodiment.

FIG. 4 is a view illustrating an example of an organic molecule according to the first embodiment.

FIGS. 5A and 5B are views illustrating examples of the organic molecule according to the first embodiment.

FIGS. 6A and 6B are views illustrating examples of the organic molecule according to the first embodiment.

FIGS. 7A and 7B are views illustrating examples of the organic molecule according to the first embodiment.

FIGS. 8A and 8B are views illustrating examples of the organic molecule according to the first embodiment.

FIG. 9 is a view illustrating an example of the organic molecule according to the first embodiment.

FIGS. 10A and 10B are views illustrating examples of the organic molecule according to the first embodiment.

FIG. 11 is a view illustrating the organic molecule according to the first embodiment.

FIGS. 12A and 12B are views illustrating examples of the organic molecule according to the first embodiment.

FIGS. 13A and 13B are views illustrating examples of the organic molecule according to the first embodiment.

FIGS. 14A and 14B are views illustrating examples of the organic molecule according to the first embodiment.

FIGS. 15A and 15B are views illustrating examples of the organic molecule according to the first embodiment.

FIG. 16 is a view illustrating an example of the organic molecule according to the first embodiment.

FIG. 17 is a view illustrating the organic molecule according to the first embodiment.

FIG. 18 is a view illustrating an operation of the organic molecular memory according to the first embodiment.

FIG. 19 is a view illustrating the operation of the organic molecular memory according to the first embodiment.

FIG. 20 is a view illustrating the operation of the organic molecular memory according to the first embodiment.

FIG. 21 is a view illustrating the operation of the organic molecular memory according to the first embodiment.

FIG. 22 is a view illustrating the operation of the organic molecular memory according to the first embodiment.

FIG. 23 is a view illustrating the operation of the organic molecular memory according to the first embodiment.

FIG. 24 is a view illustrating the operation of the organic molecular memory according to the first embodiment.

FIG. 25 is a view illustrating the operation of the organic molecular memory according to the first embodiment.

FIG. 26 is a view illustrating the operation of the organic molecular memory according to the first embodiment.

FIG. 27 is a view illustrating the operation of the organic molecular memory according to the first embodiment.

FIG. 28 is a view illustrating the operation of the organic molecular memory according to the first embodiment.

FIG. 29 is a view illustrating the operation of the organic molecular memory according to the first embodiment.

FIG. 30 is a view illustrating the operation of the organic molecular memory according to the first embodiment.

FIG. 31 is a schematic cross-sectional view of an organic molecular memory according to a modification example of the first embodiment.

FIG. 32 is an equivalent circuit diagram of a memory cell array of an organic molecular memory according to a second embodiment.

FIG. 33 is a schematic cross-sectional view of the organic molecular memory according to the second embodiment.

FIG. 34 is a view illustrating an operation of the organic molecular memory according to the second embodiment.

FIG. 35 is a view illustrating the operation of the organic molecular memory according to the second embodiment.

FIG. 36 is a view illustrating the operation of the organic molecular memory according to the second embodiment.

FIG. 37 is a view illustrating the operation of the organic molecular memory according to the second embodiment.

FIG. 38 is a view illustrating the operation of the organic molecular memory according to the second embodiment.

FIG. 39 is a view illustrating the operation of the organic molecular memory according to the second embodiment.

FIG. 40 is a view illustrating the operation of the organic molecular memory according to the second embodiment.

FIG. 41 is a view illustrating the operation of the organic molecular memory according to the second embodiment.

### DETAILED DESCRIPTION

Embodiments provide an organic molecular memory capable of implementing a large capacity.

In general, according to one embodiment, an organic molecular memory comprises a first electrode, a second electrode above the first electrode in a first direction, an organic molecule layer between the first and second electrodes and including a first molecule and a second molecule, the second molecule being closer to the second electrode than the first molecule, and a third electrode facing the second molecule. Each of the first and second molecules includes a metal complex or a fullerene derivative.

Hereinafter, embodiments will be described with reference to the drawings. In the following description, the same reference numerals are given to the same or similar members, and the description thereof will be omitted as appropriate.

For example, secondary ion mass spectrometry (SIMS), energy dispersive X-ray spectroscopy (EDX), X-ray diffraction (XRD), electron beam diffraction (EBD), X-ray photoelectron spectroscopy (XPS), synchrotron radiation X-ray absorption fine structure (XAFS), liquid chromatography, gas chromatography, or ion chromatography can be used to identify materials to form an organic molecular memory according to an embodiment.

For example, a transmission electron microscope (TEM) can be used to measure thicknesses of the materials, distances therebetween, and the like.

For example, an atomic force microscope (AFM) or a scanning tunneling microscope (STM) can be used to identify a molecular structure of an organic molecule.

In the present specification, the term “chemical bond” is a concept indicating any of a covalent bond, an ionic bond, or a metallic bond, excluding a hydrogen bond and a van der Waals bond.

### First Embodiment

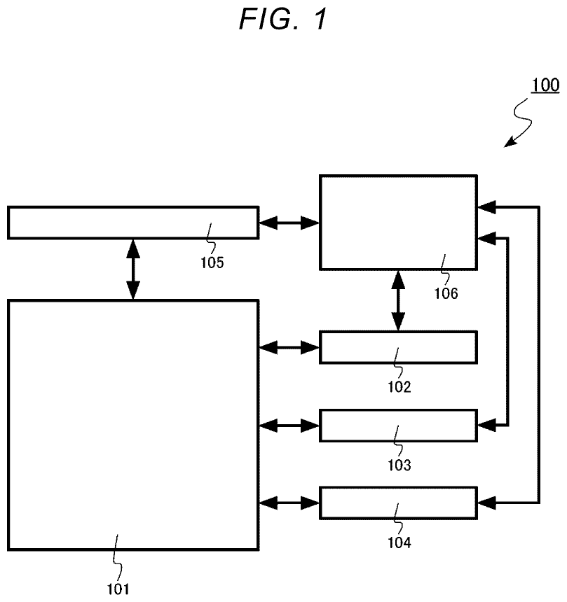

FIG. 1 shows a non-volatile organic molecular memory 100 according to a first embodiment in which memory cells are three-dimensionally disposed. In the organic molecular memory 100, the memory cells store data using charges in organic molecules. The organic molecular memory 100 performs a shift register operation.

FIG. 1 is a block diagram of the organic molecular memory 100 according to the first embodiment. As illustrated in FIG. 1, the organic molecular memory 100 includes a memory cell array 101, a write control circuit 102, a read control circuit 103, a shift control circuit 104, a sense amplifier circuit 105, and a central control circuit 106. The shift control circuit 104 is an example of a second control circuit.

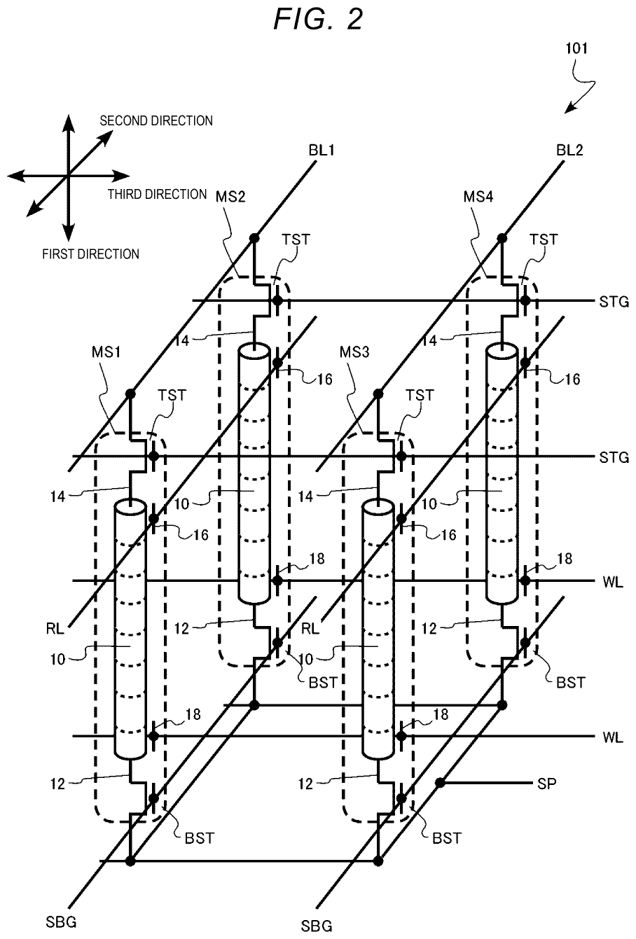

FIG. 2 is an equivalent circuit diagram of the memory cell array 101 of the organic molecular memory 100 according to the first embodiment.

As illustrated in FIG. 2, the memory cell array 101 includes a first memory string MS1, a second memory string MS2, a third memory string MS3, a fourth memory string MS4, a source plate SP, a lower select gate line SBG, an upper select gate line STG, a write line WL, a read line RL, a first bit line BL1, and a second bit line BL2.

Hereinafter, the first memory string MS1, the second memory string MS2, the third memory string MS3, and the fourth memory string MS4 may be individually or collectively referred to as a memory string MS. The first bit line BL1 and the second bit line BL2 may be individually or collectively referred to as a bit line BL.

Each of the first memory string MS1, the second memory string MS2, the third memory string MS3, and the fourth memory string MS4 includes an organic molecule layer 10, a lower electrode 12, an upper electrode 14, a read electrode 16, a write electrode 18, a lower select gate transistor BST, and an upper select gate transistor TST.

In the memory cell array 101, a direction from the lower electrode 12 to the upper electrode 14 is defined as the first direction. A direction intersecting with the first direction is defined as a second direction. A direction intersecting with the first direction and the second direction is defined as a third direction. For example, the second direction is perpendicular to the first direction. For example, the third direction is perpendicular to the first direction and the second direction.

As illustrated in FIG. 2, the first memory string MS1, the second memory string MS2, the third memory string MS3, and the fourth memory string MS4 extend in the first direction.

The first bit line BL1 and the second bit line BL2 extend in the second direction. The first memory string MS1 and the second memory string MS2 are provided between the first bit line BL1 and the source plate SP. The third memory string MS3 and the fourth memory string MS4 are provided between the second bit line BL2 and the source plate SP.

The first bit line BL1 extends above the first memory string MS1 and the second memory string MS2 in the first direction. The first bit line BL1 is electrically connected to the first memory string MS1 and the second memory string MS2.

The second bit line BL2 extends above the third memory string MS3 and the fourth memory string MS4 in the first direction. The second bit line BL2 is electrically connected to the third memory string MS3 and the fourth memory string MS4. The second bit line BL2 is electrically separated or insulated from the first bit line BL1.

The organic molecule layer 10 includes a plurality of organic molecules. Each of the plurality of organic molecules functions as a memory cell.

The lower select gate transistor BST is provided between the lower electrode 12 and the source plate SP. The lower select gate line SBG extends in the second direction.

The lower select gate transistor BST is controlled to enter an ON state or an OFF state by a gate voltage applied to the lower select gate line SBG. The lower select gate transistor BST has a function of selecting a desired memory string MS from a plurality of memory strings MS. The lower select gate transistor BST may not be provided.

The upper select gate transistor TST is provided between the upper electrode 14 and the first bit line BL1 or between the upper electrode 14 and the second bit line BL2. The upper select gate line STG extends in the third direction.

The upper select gate transistor TST is controlled to enter an ON state or an OFF state by a gate voltage applied to the upper select gate line STG. The upper select gate transistor TST has a function of selecting the desired memory string MS from the plurality of memory strings MS.

One desired memory string MS can be selected by controlling the lower select gate transistor BST and the upper select gate transistor TST.

The write line WL extends in the third direction. The write line WL is connected to the write electrode 18. Data is written into the organic molecules facing the write electrode 18 by a write voltage applied to the write line WL.

For example, the write electrode 18 of the first memory string MS1 and the write electrode 18 of the third memory string MS3 are electrically connected to each other by the write line WL. For example, the write electrode 18 of the second memory string MS2 and the write electrode 18 of the fourth memory string MS4 are electrically connected to each other by the write line WL.

The read line RL extends in the second direction. The read line RL is connected to the read electrode 16. Data of the organic molecules facing the read electrode 16 is read by detecting a current flowing between the read electrode 16 and the upper electrode 14.

For example, the read electrode 16 of the first memory string MS1 and the read electrode 16 of the second memory string MS2 are electrically connected to each other by the read line RL. For example, the read electrode 16 of the third memory string MS3 and the read electrode 16 of the fourth memory string MS4 are electrically connected to each other by the read line RL.

For example, the write control circuit 102 has a function of selecting the write line WL and controlling a voltage to be applied to the selected write line WL.

For example, the read control circuit 103 has a function of selecting the read line RL and controlling a voltage to be applied to the selected read line RL.

The shift control circuit 104 has a function of controlling a shift register operation of the memory string MS. The shift control circuit 104 has a function of transmitting data stored in an organic molecule OM in the first direction by applying a shift voltage between the lower electrode 12 and the upper electrode 14 of the memory string MS.

The sense amplifier circuit 105 has a function of detecting the data stored in the organic molecule OM by amplifying a current flowing in the bit line BL or a voltage of the bit line BL.

The central control circuit 106 controls an operation of the organic molecular memory 100. The central control circuit 106 controls the write control circuit 102, the read control circuit 103, the shift control circuit 104, and the sense amplifier circuit 105.

For example, the write control circuit 102, the read control circuit 103, the shift control circuit 104, the sense amplifier circuit 105, and the central control circuit 106 are formed by transistors and wire layers on a semiconductor substrate (not illustrated).

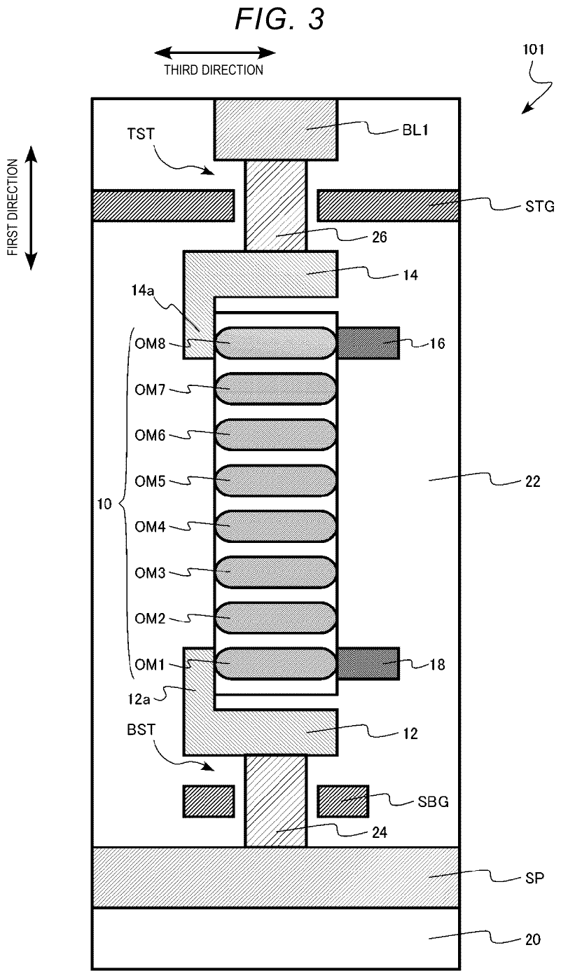

FIG. 3 is a schematic cross-sectional view of the organic molecular memory 100 according to the first embodiment. FIG. 3 is a cross-sectional view of the memory cell array 101. FIG. 3 is a cross-sectional view parallel to the first direction and the third direction. FIG. 3 is a cross section including the first memory string MS1.

The memory cell array 101 includes the organic molecule layer 10, the lower electrode 12, the upper electrode 14, the read electrode 16, the write electrode 18, a substrate insulating layer 20, an interlayer insulating layer 22, the source plate SP, the first bit line BL1, the lower select gate transistor BST, and the upper select gate transistor TST.

The organic molecule layer 10 includes a first organic molecule OM1, a second organic molecule OM2, a third organic molecule OM3, a fourth organic molecule OM4, a fifth organic molecule OM5, a sixth organic molecule OM6, a seventh organic molecule OM7, and an eighth organic molecule OM8.

Hereinafter, the first organic molecule OM1, the second organic molecule OM2, the third organic molecule OM3, the fourth organic molecule OM4, the fifth organic molecule OM5, the sixth organic molecule OM6, the seventh organic molecule OM7, and the eighth organic molecule OM8 may be individually or collectively referred to as the organic molecule OM.

The lower select gate transistor BST includes a first semiconductor layer 24. The upper select gate transistor TST includes a second semiconductor layer 26.

For example, the substrate insulating layer 20 is made of an oxide. For example, the substrate insulating layer 20 is made of a silicon oxide.

The source plate SP is provided on the substrate insulating layer 20. The source plate SP is made of a conductor. For example, the source plate SP is made of a metal or a semiconductor. For example, the source plate SP is made of tungsten.

The first semiconductor layer 24 is provided between the source plate SP and the lower electrode 12. For example, the first semiconductor layer 24 is in contact with the source plate SP and the lower electrode 12.

When the lower select gate transistor BST enters the ON state, a channel is formed in the first semiconductor layer 24. For example, the first semiconductor layer 24 is made of polycrystalline silicon.

A part of the source plate SP functions as a source and drain region of the lower select gate transistor BST. The lower electrode 12 functions as a source and drain region of the lower select gate transistor BST.

A part of the lower select gate line SBG functions as a gate electrode of the lower select gate transistor BST. A gate insulating film (not illustrated) is provided between the part of the lower select gate line SBG and the first semiconductor layer 24.

The lower select gate line SBG is made of a conductor. For example, the lower select gate line SBG is made of a metal. For example, the lower select gate line SBG is made of tungsten.

The lower electrode 12 is provided between the source plate SP and the organic molecule layer 10. The lower electrode 12 is provided between the first semiconductor layer 24 and the organic molecule layer 10. A dielectric layer is provided between the lower electrode 12 and the organic molecule layer 10. For example, a part of the interlayer insulating layer 22 is provided between the lower electrode 12 and the organic molecule layer 10. The part of the interlayer insulating layer 22 electrically separates the lower electrode 12 and the organic molecule layer 10 from each other. The part of the interlayer insulating layer 22 electrically separates the lower electrode 12 and the first organic molecule OM1 from each other.

The lower electrode 12 includes a first part 12a. The first part 12a faces the first organic molecule OM1 in a direction intersecting with the first direction. For example, the first part 12a faces the first organic molecule OM1 in a direction orthogonal to the first direction. For example, the first part 12a faces the first organic molecule OM1 in the third direction.

The first organic molecule OM1 is provided between the first part 12a and the write electrode 18. For example, the first organic molecule OM1 is positioned between the first part 12a and the write electrode 18 in a direction intersecting with the first direction. For example, the first organic molecule OM1 is positioned between the first part 12a and the write electrode 18 in a direction orthogonal to the first direction. For example, the first organic molecule OM1 is positioned between the first part 12a and the write electrode 18 in the third direction.

For example, a distance between the first part 12a and the first organic molecule OM1 is smaller than a length of the first organic molecule OM1 in the third direction. For example, the distance between the first part 12a and the first organic molecule OM1 is smaller than a disposition pitch of the organic molecules OM in the first direction.

The lower electrode 12 is made of a conductor. For example, the lower electrode 12 is made of a metal or a semiconductor. For example, the lower electrode 12 is made of tungsten.

The organic molecule layer 10 is provided between the lower electrode 12 and the upper electrode 14. The organic molecule layer 10 extends in the first direction from the lower electrode 12 to the upper electrode 14.

The first organic molecule OM1, the second organic molecule OM2, the third organic molecule OM3, the fourth organic molecule OM4, the fifth organic molecule OM5, the sixth organic molecule OM6, the seventh organic molecule OM7, and the eighth organic molecule OM8 are stacked in the first direction.

Chemical bonds are not present between two organic molecules OM adjacent to each other in the first direction. For example, covalent bonds are not present between two organic molecules OM adjacent to each other in the first direction.

For example, chemical bonds are not present between the first organic molecule OM1 and the second organic molecule OM2 adjacent to each other in the first direction. For example, covalent bonds are not present between the first organic molecule OM1 and the second organic molecule OM2.

For example, lengths of the organic molecule OM in the second direction and the third direction are between 5 nm and 20 nm. For example, the disposition pitch of the organic molecules OM in the first direction is between 1 nm and 5 nm.

For example, the lengths of the organic molecule OM in the second direction and the third direction are greater than a length of the organic molecule OM in the first direction.

The organic molecule OM includes a metal complex or a fullerene derivative. For example, the organic molecule OM has a degenerate energy level. For example, the organic molecule OM includes a metal complex having a degenerate energy level or a fullerene derivative having a degenerate energy level.

For example, the organic molecule OM is a liquid crystal molecule. For example, the organic molecule OM is a metal complex that is a liquid crystal molecule, or a fullerene derivative that is a liquid crystal molecule. The liquid crystal molecule is a molecule that may enter an intermediate state between solid and liquid.

For example, the organic molecule OM includes a double-decker complex including a side chain. The double-decker complex is a metal complex having a structure in which two planar molecules are stacked on each other. For example, the organic molecule OM includes two phthalocyanine skeletons stacked on each other and includes one rare earth element selected from the group including lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu). For example, in the organic molecule OM, the rare earth element is interposed between the two phthalocyanine skeletons.

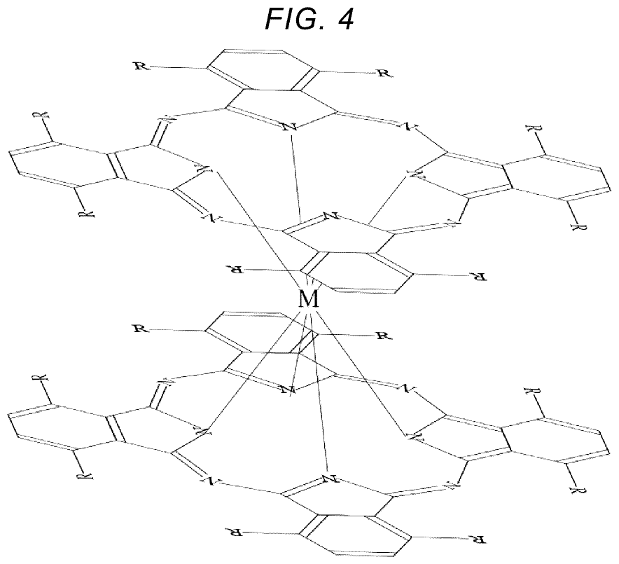

FIG. 4 is a view illustrating an example of an organic molecule according to the first embodiment. The organic molecule in FIG. 4 is a double-decker phthalocyanine complex. Reference numeral “M” in the molecular structure in FIG. 4 denotes the one rare earth element selected from the group including lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

The double-decker phthalocyanine complex illustrated in FIG. 4 includes two phthalocyanine molecules that are planar molecules stacked on each other. The double-decker phthalocyanine complex illustrated in FIG. 4 includes two phthalocyanine skeletons stacked on each other. For example, a plane formed by each phthalocyanine skeleton intersects with the first direction in the organic molecule layer 10. For example, the plane formed by each phthalocyanine skeleton is substantially orthogonal to the first direction in the organic molecule layer 10. For example, the plane formed by each phthalocyanine skeleton is provided along a plane perpendicular to the first direction in the organic molecule layer 10.

The double-decker phthalocyanine complex illustrated in FIG. 4 includes a side chain. Reference numeral “R” in the molecular structure in FIG. 4 denotes the side chain. For example, the side chain R is an alkyl chain having a carbon number between 3 and 18. For example, the side chain R includes an alkyl group, an ortho-alkyl group, or a thio-alkyl group.

The double-decker phthalocyanine complex illustrated in FIG. 4 has a degenerate energy level. The number of states at the same energy level is doubled because of the two phthalocyanine skeletons stacked on each other.

For example, the metal complex in the organic molecule OM is a metallocene derivative including a side chain. For example, the metallocene derivative includes one metal element selected from the group including iron (Fe), copper (Cu), cobalt (Co), titanium (Ti), nickel (Ni), zinc (Zn), and chromium (Cr). For example, the side chain in the metallocene derivative is an alkyl chain having a carbon number between 3 and 18. For example, the side chain R includes an alkyl group, an ortho-alkyl group, or a thio-alkyl group.

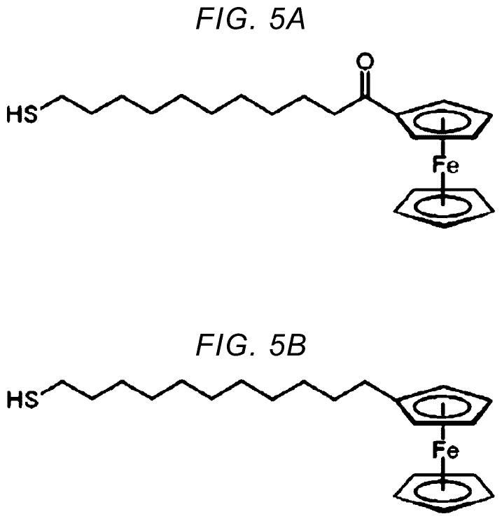

FIGS. 5A and 5B are views illustrating examples of the organic molecule according to the first embodiment. The organic molecules in FIGS. 5A and 5B are metallocene derivatives. The metallocene derivatives in FIGS. 5A and 5B include iron (Fe) as a metal element. The metallocene derivatives in FIGS. 5A and 5B have degenerate energy levels.

For example, the metal complex in the organic molecule OM is a metalloporphyrin derivative including a side chain. For example, the metalloporphyrin derivative includes one metal element selected from the group including iron (Fe), copper (Cu), cobalt (Co), titanium (Ti), nickel (Ni), zinc (Zn), and chromium (Cr). For example, the side chain in the metalloporphyrin derivative is an alkyl chain having a carbon number between 3 and 18. For example, the side chain R includes an alkyl group, an ortho-alkyl group, or a thio-alkyl group.

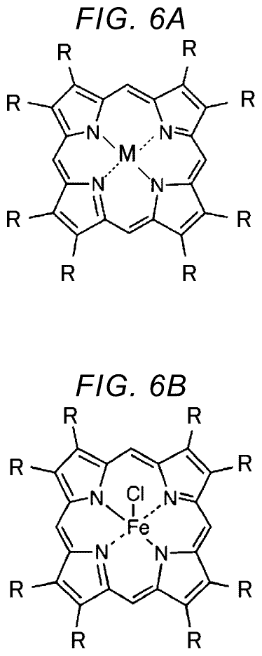

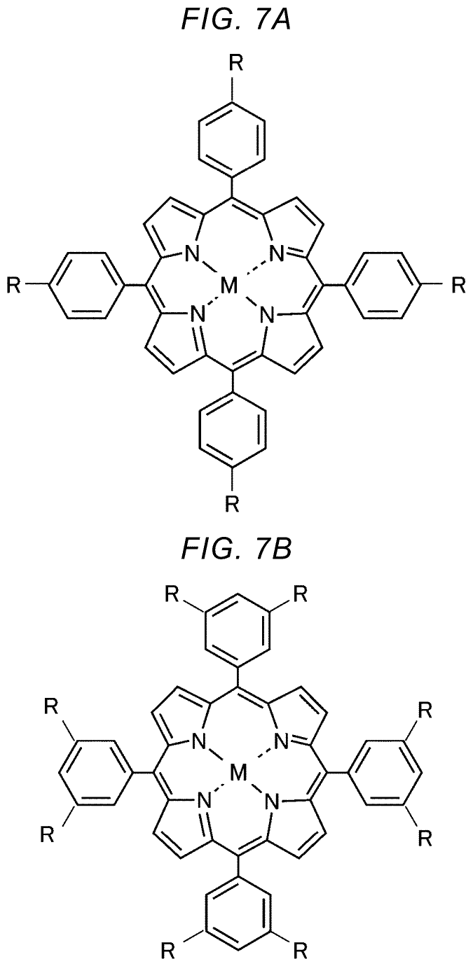

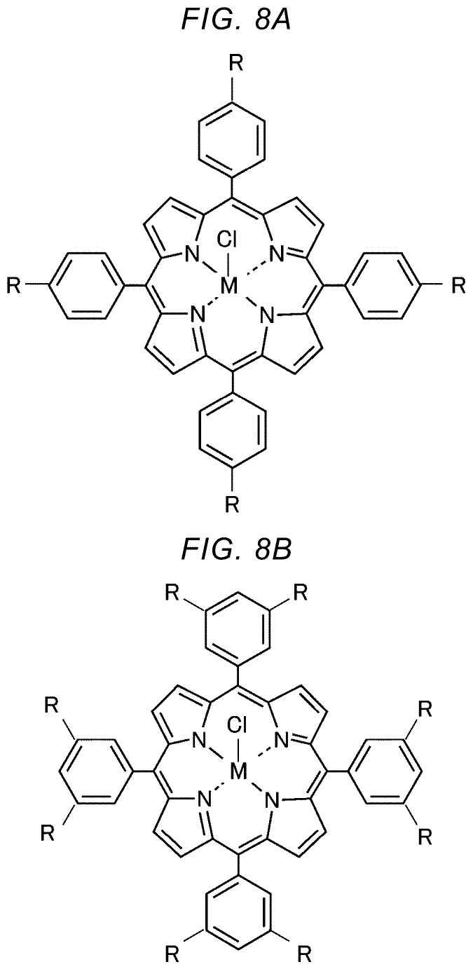

FIGS. 6A, 6B, 7A, 7B, 8A, and 8B are views illustrating examples of the organic molecule according to the first embodiment. The organic molecules in FIGS. 6A, 6B, 7A, 7B, 8A, and 8B are metalloporphyrin derivatives. For example, reference numeral “M” in the molecular structures in FIGS. 6A, 6B, 7A, 7B, 8A, and 8B includes one metal element selected from the group including iron (Fe), copper (Cu), cobalt (Co), titanium (Ti), nickel (Ni), zinc (Zn), and chromium (Cr). In the organic molecules in FIGS. 6B, 8A, and 8B, chlorine (Cl) is bonded to the metal element.

In the molecular structures in FIGS. 6A, 6B, 7A, 7B, 8A, and 8B, reference numeral “R” denotes a side chain. For example, the side chain R is an alkyl chain having a carbon number between 3 and 18. For example, the side chain R includes an alkyl group, an ortho-alkyl group, or a thio-alkyl group.

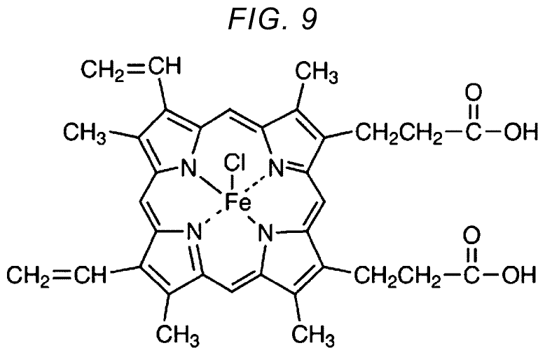

FIG. 9 is a view illustrating an example of the organic molecule according to the first embodiment. FIG. 9 illustrates a metalloporphyrin derivative. FIG. 9 is an example of the metalloporphyrin derivative in FIG. 6B. The metalloporphyrin derivative illustrated in FIG. 9 includes iron (Fe) as a metal element. In the metalloporphyrin derivative illustrated in FIG. 9, chlorine (Cl) is bonded to iron (Fe).

The metalloporphyrin derivatives illustrated in FIGS. 6A, 6B, 7A, 7B, 8A, 8B, and 9 have degenerate energy levels.

For example, the metal complex in the organic molecule OM is a metallophthalocyanine derivative including a side chain. For example, the metallophthalocyanine derivative includes one metal element selected from the group including iron (Fe), copper (Cu), cobalt (Co), titanium (Ti), nickel (Ni), zinc (Zn), and chromium (Cr). For example, the side chain in the metallophthalocyanine derivative is an alkyl chain having a carbon number between 3 and 18. For example, the side chain R includes an alkyl group, an ortho-alkyl group, or a thio-alkyl group.

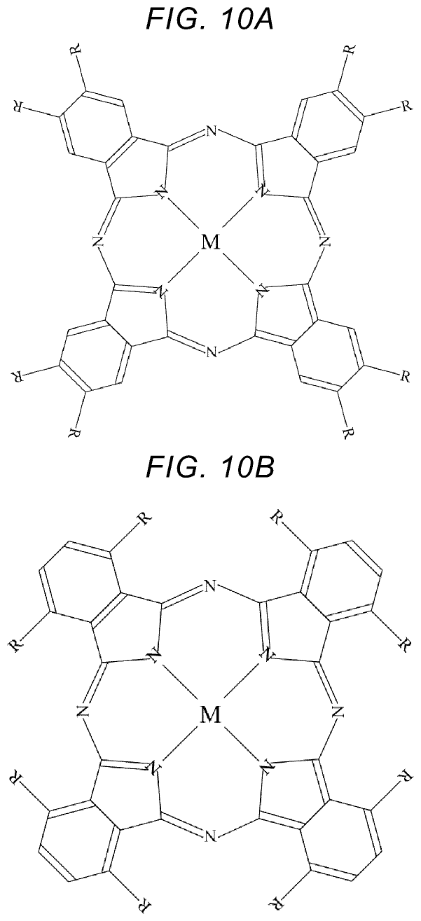

FIGS. 10A and 10B are views illustrating examples of the organic molecule according to the first embodiment. The organic molecules in FIGS. 10A and 10B are metallophthalocyanine derivatives. For example, reference numeral “M” in the molecular structures in FIGS. 10A and 10B includes one metal element selected from the group including iron (Fe), copper (Cu), cobalt (Co), titanium (Ti), nickel (Ni), zinc (Zn), and chromium (Cr).

Reference numeral “R” in the molecular structures in FIGS. 10A and 10B denotes the side chain. For example, the side chain R is an alkyl chain having a carbon number between 3 and 18. For example, the side chain R includes an alkyl group, an ortho-alkyl group, or a thio-alkyl group.

The metallophthalocyanine derivatives illustrated in FIGS. 10A and 10B have degenerate energy levels.

For example, when the organic molecule OM according to the first embodiment is a metal complex, each organic molecule OM has an annular structure of which constituting atoms form a plane. For example, the plane formed by the constituting atoms of the annular structure of the organic molecule OM intersects with the first direction. For example, the planes formed by the constituting atoms of the annular structures of two organic molecules OM disposed adjacent to each other face each other in the first direction.

When the organic molecule OM according to the first embodiment is a metal complex, each organic molecule OM includes a metal element. For example, a direction in which two metal elements in two organic molecules OM, respectively, arranged adjacent to each other are connected is a direction along the first direction. For example, the direction in which the metal elements of two organic molecules OM arranged adjacent to each other are connected is the first direction.

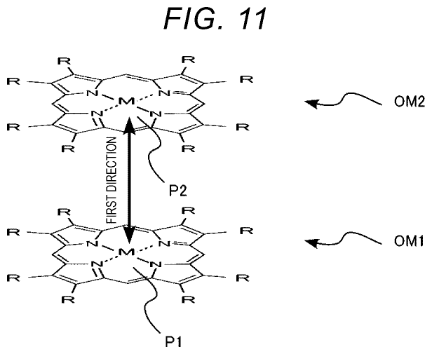

FIG. 11 is a view illustrating the organic molecule according to the first embodiment. FIG. 11 is a view illustrating an example of disposition of the first organic molecule OM1 and the second organic molecule OM2. The first organic molecule OM1 and the second organic molecule OM2 are metalloporphyrin derivatives.

The first organic molecule OM1 has a first annular structure of which constituting atoms form a first plane P1. The first annular structure is a porphyrin skeleton. The second organic molecule OM2 has a second annular structure of which constituting atoms form a second plane P2. The second annular structure is a porphyrin skeleton.

The first plane P1 and the second plane P2 intersect with the first direction. For example, the first plane P1 and the second plane P2 are substantially orthogonal to the first direction. The first plane P1 and the second plane P2 face each other in the first direction. In other words, the first plane P1 and the second plane P2 face each other in a direction in which the first organic molecule OM1 and the second organic molecule OM2 are stacked on each other.

The first organic molecule OM1 and the second organic molecule OM2 have metal elements (M in FIG. 11). A direction in which two metal elements M of the first organic molecule OM1 and the second organic molecule OM2 disposed adjacent to each other are connected is a direction along the first direction. For example, the direction in which the two metal elements M of the first organic molecule OM1 and the second organic molecule OM2 arranged adjacent to each other are connected is the first direction.

For example, the organic molecules OM in the organic molecule layer 10 satisfy the disposition relationship illustrated in FIG. 11 even if the organic molecules OM are not adjacent to each other in the first direction. For example, the first organic molecule OM1 has the first annular structure of which constituting atoms form the first plane. The eighth organic molecule OM8 has the second annular structure of which constituting atoms form the second plane. The first plane and the second plane face each other in the first direction.

In the present specification, the term “face” is a concept including presence of other elements between two elements facing each other. For example, one or more organic molecules may be present between the first plane and the second plane facing each other. For example, other organic molecules may not be present between the first plane and the second plane facing each other.

For example, the organic molecule OM is a fullerene derivative. For example, the organic molecule OM is a fullerene derivative having a degenerate energy level. For example, the organic molecule OM is a fullerene derivative including a side chain. For example, the side chain in the fullerene derivative includes an alkyl chain having a carbon number between 3 and 18.

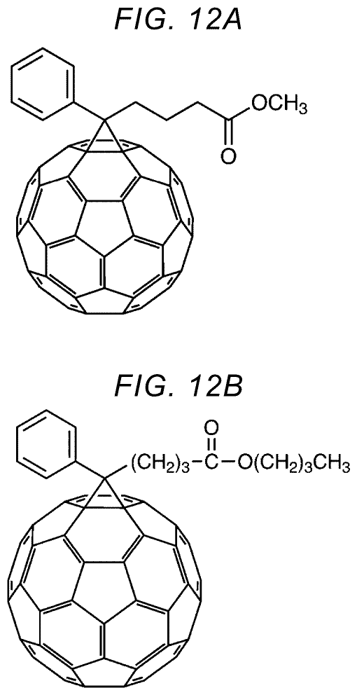

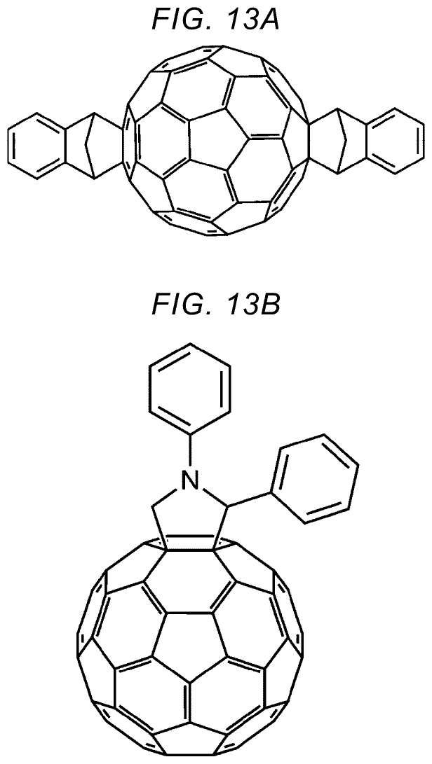

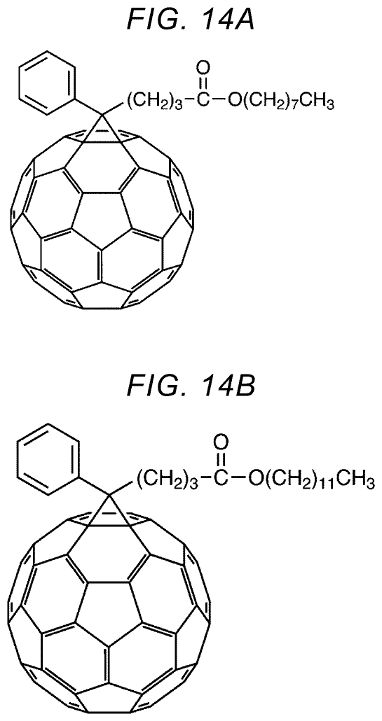

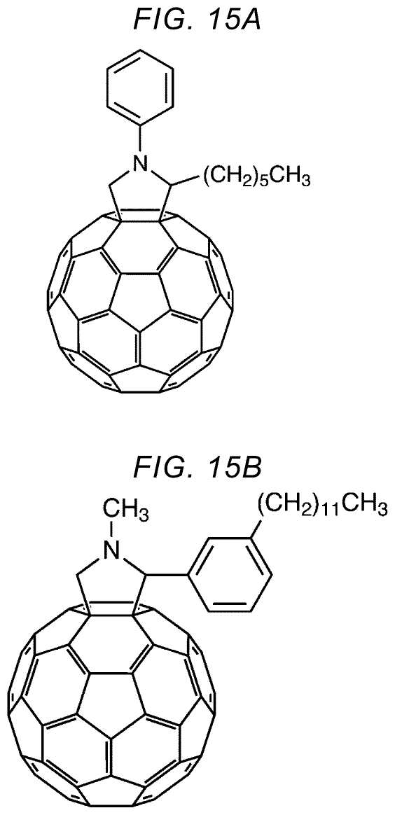

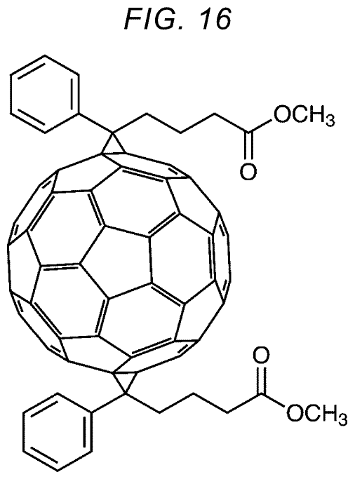

FIGS. 12A, 12B, 13A, 13B, 14A, 14B, 15A, 15B, and 16 are views illustrating examples of the organic molecule according to the first embodiment. The organic molecules in FIGS. 12A, 12B, 13A, 13B, 14A, 14B, 15A, 15B, and 16 are fullerene derivatives including a side chain.

The fullerene derivatives illustrated in FIGS. 12A, 12B, 13A, 13B, 14A, 14B, 15A, 15B, and 16 have degenerate energy levels.

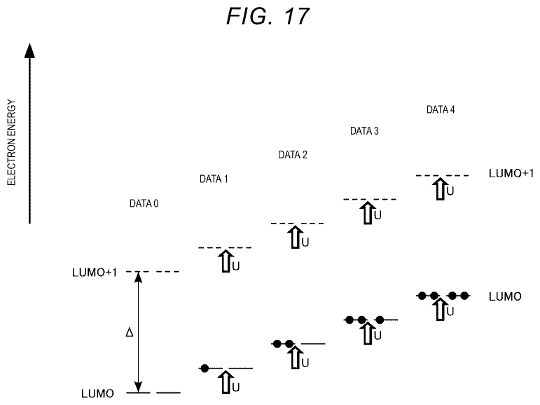

FIG. 17 is a view illustrating the organic molecule according to the first embodiment. The organic molecule OM according to the first embodiment has a degenerate energy level. The organic molecule OM according to the first embodiment has a degenerate orbital. Accordingly, the organic molecule OM according to the first embodiment has a plurality of states at the same energy level. Thus, the organic molecule OM according to the first embodiment can store three or more charges at the same energy level.

FIG. 17 is a view illustrating an electronic state of the organic molecule OM having two states at the same energy level. FIG. 17 illustrates a lowest unoccupied molecular orbital (LUMO) of the organic molecule OM and an orbital (LUMO+1) at one level above the LUMO. In FIG. 17, one black circle indicates one electron.

As illustrated in FIG. 17, two electrons can occupy each of the two states. Accordingly, as illustrated in FIG. 17, the number of electrons entering the LUMO is considered to be 0, 1, 2, 3, and 4. When data 0 indicates 0 electrons, data 1 indicates 1 electron, data 2 indicates 2 electrons, data 3 indicates 3 electrons, and data 4 indicates four electrons as the number of electrons entering the LUMO, the organic molecule OM can store five values.

Accordingly, the organic molecular memory 100 including the organic molecule OM functions as a multivalued memory capable of storing multiple values in the same memory cell.

As illustrated in FIG. 17, when electrons enter the LUMO, on-site Coulomb repulsion occurs, and the energy level shifts upward. For example, when one electron enters, the LUMO is shifted upward by U eV. For example, when one electron further enters, the LUMO further shifts upward by U eV. Accordingly, for example, a difference of 4U eV in energy of the LUMO occurs between the data 0 and the data 4. In FIG. 17, an energy difference between the LUMO and the (LUMO+1) is denoted by Δ (delta) eV.

The upper electrode 14 is provided on the organic molecule layer 10. The upper electrode 14 is provided between the organic molecule layer 10 and the first bit line BL1. The organic molecule layer 10 is provided between the lower electrode 12 and the upper electrode 14.

The upper electrode 14 includes a second part 14a. The second part 14a faces the eighth organic molecule OM8 in a direction intersecting with the first direction. For example, the second part 14a faces the eighth organic molecule OM8 in a direction orthogonal to the first direction. For example, the second part 14a faces the eighth organic molecule OM8 in the third direction.

The eighth organic molecule OM8 is provided between the second part 14a and the read electrode 16. For example, the eighth organic molecule OM8 is positioned between the second part 14a and the read electrode 16 in a direction intersecting with the first direction. For example, the eighth organic molecule OM8 is positioned between the second part 14a and the read electrode 16 in a direction orthogonal to the first direction. For example, the eighth organic molecule OM8 is positioned between the second part 14a and the read electrode 16 in the third direction.

For example, a distance between the second part 14a and the eighth organic molecule OM8 is smaller than a length of the eighth organic molecule OM8 in the third direction. For example, the distance between the second part 14a and the eighth organic molecule OM8 is smaller than the disposition pitch of the organic molecules OM in the first direction.

The upper electrode 14 is made of a conductor. For example, the upper electrode 14 is made of a metal or a semiconductor. For example, the upper electrode 14 is made of tungsten.

The write electrode 18 faces the first organic molecule OM1 in the third direction. The first organic molecule OM1 is provided between the write electrode 18 and the first part 12a of the lower electrode 12 in the third direction. For example, a distance between the write electrode 18 and the first organic molecule OM1 is smaller than the length of the first organic molecule OM1 in the third direction. For example, the distance between the write electrode 18 and the first organic molecule OM1 is smaller than the disposition pitch of the organic molecules OM in the first direction.

The write electrode 18 has a function of injecting charges into the first organic molecule OM1. For example, the write electrode 18 has a function of injecting electrons into the first organic molecule OM1.

For example, the write electrode 18 is electrically connected to the write line WL extending in the third direction, in a direction normal to the drawing. While FIG. 3 illustrates a structure in which the write electrode 18 faces the first organic molecule OM1 in the third direction, a structure in which the write electrode 18 faces the first organic molecule OM1 in the second direction may also be used.

The write electrode 18 is made of a conductor. For example, the write electrode 18 is made of a metal or a semiconductor. For example, the write electrode 18 is made of tungsten.

For example, the read electrode 16 faces the eighth organic molecule OM8 in a direction intersecting with the first direction. For example, the read electrode 16 faces the eighth organic molecule OM8 in a direction orthogonal to the first direction. For example, the read electrode 16 faces the eighth organic molecule OM8 in the third direction. For example, a distance between the read electrode 16 and the eighth organic molecule OM8 is smaller than the length of the eighth organic molecule OM8 in the third direction. For example, the distance between the read electrode 16 and the eighth organic molecule OM8 is smaller than the disposition pitch of the organic molecules OM in the first direction.

The read electrode 16 has a function of causing a current to flow into the eighth organic molecule OM8. The read electrode 16 as one terminal and the upper electrode 14 as the other terminal cause the current to flow into the eighth organic molecule OM8.

For example, the read electrode 16 extends in a direction normal to the drawing, that is, the second direction.

The read electrode 16 is made of a conductor. For example, the read electrode 16 is made of a metal or a semiconductor. For example, the read electrode 16 is made of tungsten.

The upper select gate transistor TST includes the second semiconductor layer 26. The second semiconductor layer 26 is provided between the upper electrode 14 and the first bit line BL1. For example, the second semiconductor layer 26 is in contact with the upper electrode 14 and the first bit line BL1.

When the upper select gate transistor TST enters the ON state, a channel is formed in the second semiconductor layer 26. For example, the second semiconductor layer 26 is polycrystalline silicon.

The upper electrode 14 functions as a source and drain region of the upper select gate transistor TST. A part of the first bit line BL1 functions as the source and drain region of the upper select gate transistor TST.

A part of the upper select gate line STG functions as a gate electrode of the upper select gate transistor TST. A gate insulating film (not illustrated) is provided between the part of the upper select gate line STG and the second semiconductor layer 26.

The upper select gate line STG is made of a conductor. For example, the upper select gate line STG is made of a metal. For example, the upper select gate line STG is made of tungsten.

The first bit line BL1 is made of a conductor. For example, the first bit line BL1 is made of a metal. For example, the first bit line BL1 is made of tungsten.

For example, the interlayer insulating layer 22 is made of an oxide. For example, the interlayer insulating layer 22 is made of a silicon oxide.

Next, the operation of the organic molecular memory 100 will be described.

During a write operation and a read operation, the organic molecular memory 100 sequentially transmits data stored in a plurality of organic molecules OM stacked on each other in the organic molecule layer 10 to adjacent organic molecules OM. The organic molecular memory 100 performs a so-called shift register operation during the write operation and the read operation.

Hereinafter, an example in which the organic molecule OM can store five values including the data 0 to the data 4 as illustrated in FIG. 17 will be described.

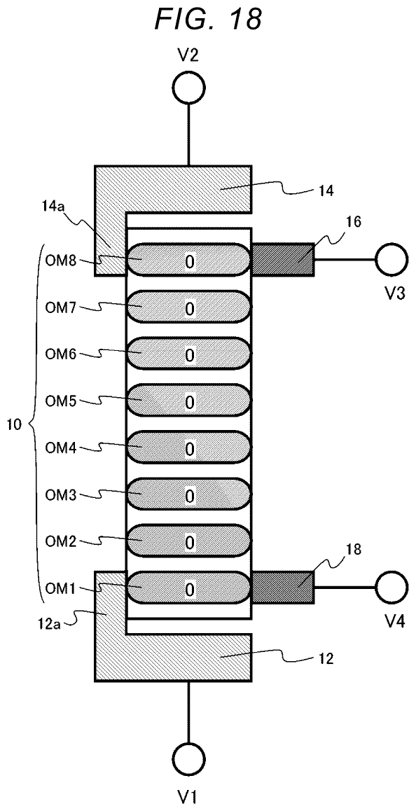

FIGS. 18, 19, 20, 21, 22, 23, 24, 25, 26, 27, 28, 29, and 30 are views illustrating the operation of the organic molecular memory 100 according to the first embodiment.

FIG. 18 illustrates an initial state of the operation of the organic molecular memory 100. In the operation of the organic molecular memory 100, a first voltage V1, a second voltage V2, a third voltage V3, and a fourth voltage V4 are applied to the lower electrode 12, the upper electrode 14, the read electrode 16, and the write electrode 18, respectively.

As illustrated in FIG. 18, as the initial state of the operation of the organic molecular memory 100, data stored in all organic molecules OM is considered to be the data 0.

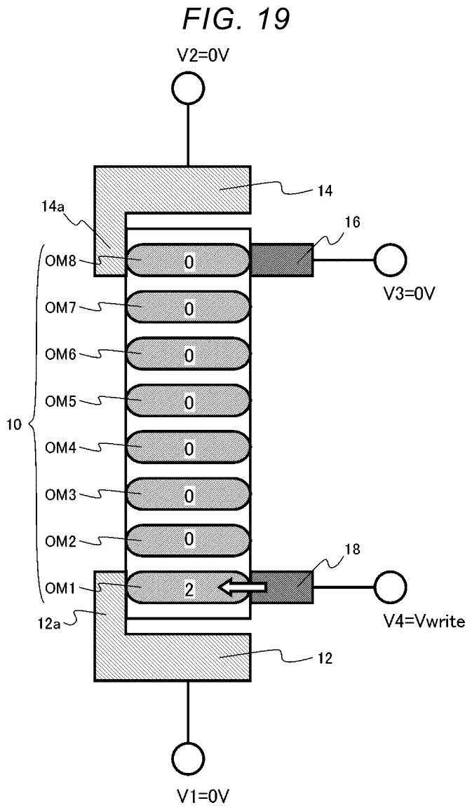

First, for example, as illustrated in FIG. 19, writing data into the first organic molecule OM1 is considered. In writing data into the first organic molecule OM1, the fourth voltage V4 is set to a voltage lower than the first voltage V1. For example, the first voltage V1 is set to 0 V, and the fourth voltage V4 is set to a write voltage Vwrite. The write voltage Vwrite is a negative voltage. For example, the write voltage Vwrite is a voltage applied between the lower electrode 12 and the write electrode 18.

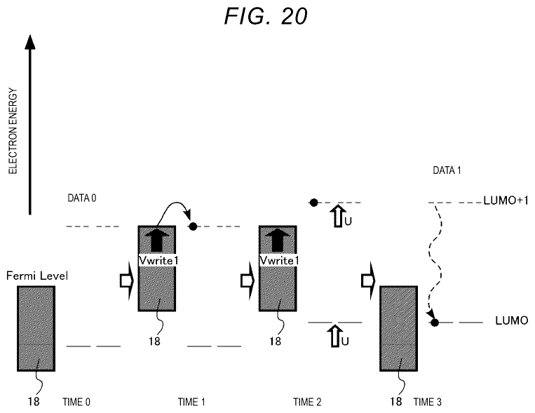

FIG. 20 is a view illustrating the write operation of data into the first organic molecule OM1. FIG. 20 is a view illustrating writing of the data 1 into the first organic molecule OM1. That is, FIG. 20 is a view illustrating injection of one electron into the first organic molecule OM1. FIG. 20 is a view illustrating temporal changes in an electronic state of the first organic molecule OM1 and in a Fermi level of the write electrode 18.

Before the data 1 is written, data stored in the first organic molecule OM1 is the data 0 (time 0). Next, a first write voltage Vwrite1 is applied to the write electrode 18 (time 1). The first write voltage Vwrite1 is a negative voltage. By applying the first write voltage Vwrite1, the Fermi level of the write electrode 18 is increased, and the Fermi level of the write electrode 18 and the (LUMO+1) of the first organic molecule OM1 are aligned with each other. By aligning the Fermi level of the write electrode 18 and the (LUMO+1) of the first organic molecule OM1 with each other, one electron is injected into the (LUMO+1) from the write electrode 18 through tunneling.

When one electron is injected into the (LUMO+1), on-site Coulomb repulsion occurs, and the LUMO and (LUMO+1) of the first organic molecule OM1 are increased by U eV (time 2). The increase in the (LUMO+1) generates an energy difference between the (LUMO+1) and the Fermi level of the write electrode 18. Accordingly, a second electron is not injected into the (LUMO+1) from the write electrode 18.

Then, application of the first write voltage Vwrite1 to the write electrode 18 is stopped (time 3). Then, after a certain amount of time, the electron of the (LUMO+1) moves to the LUMO and stabilizes. That is, the electron of the (LUMO+1) in an excited state moves to the LUMO and stabilizes through energy dissipation.

Through the above process, the data 1 is written into the first organic molecule OM1. After the data 1 is written into the first organic molecule OM1, the LUMO and the (LUMO+1) of the first organic molecule OM1 are in a state of having higher energy than the data 0 by U eV.

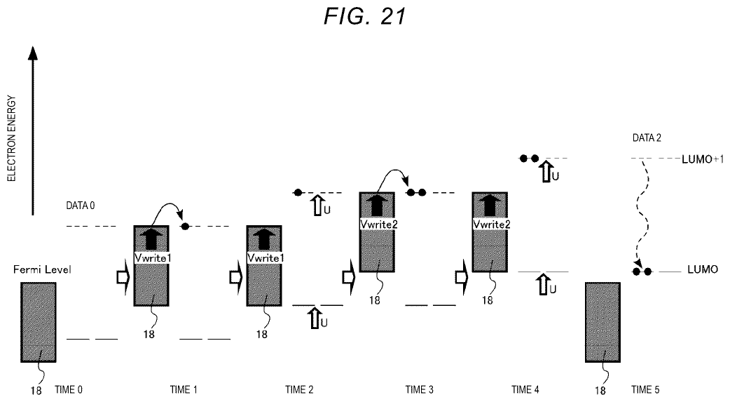

FIG. 21 is a view illustrating the write operation of data into the first organic molecule OM1. FIG. 21 is a view illustrating writing of the data 2 into the first organic molecule OM1. That is, FIG. 21 is a view illustrating injection of two electrons into the first organic molecule OM1. FIG. 21 is a view illustrating temporal changes in the electronic state of the first organic molecule OM1 and in the Fermi level of the write electrode 18.

Before the data 2 is written, data stored in the first organic molecule OM1 is the data 0 (time 0). Next, the first write voltage Vwrite1 is applied to the write electrode 18 (time 1). The first write voltage Vwrite1 is a negative voltage. By applying the first write voltage Vwrite1, the Fermi level of the write electrode 18 is increased, and the Fermi level of the write electrode 18 and the (LUMO+1) of the first organic molecule OM1 are aligned with each other. By aligning the Fermi level of the write electrode 18 and the (LUMO+1) of the first organic molecule OM1 with each other, one electron is injected into the (LUMO+1) from the write electrode 18 through tunneling.

When one electron is injected into the (LUMO+1), on-site Coulomb repulsion occurs, and the LUMO and (LUMO+1) of the first organic molecule OM1 are increased by U eV (time 2). The increase in the (LUMO+1) generates an energy difference between the (LUMO+1) and the Fermi level of the write electrode 18. Accordingly, the second electron is not injected into the (LUMO+1) from the write electrode 18.

Next, a second write voltage Vwrite2 is applied to the write electrode 18 (time 3). The second write voltage Vwrite2 is a negative voltage. The second write voltage Vwrite2 is a voltage different from the first write voltage Vwrite1. The second write voltage Vwrite2 is a voltage having a greater absolute value than the first write voltage Vwrite1.

By applying the second write voltage Vwrite2, the Fermi level of the write electrode 18 is further increased, and the Fermi level of the write electrode 18 and the (LUMO+1) of the first organic molecule OM1 are aligned with each other. By aligning the Fermi level of the write electrode 18 and the (LUMO+1) of the first organic molecule OM1 with each other, the second electron is injected into the (LUMO+1) from the write electrode 18 through tunneling.

When the second electron is injected into the (LUMO+1), on-site Coulomb repulsion occurs, and the LUMO and (LUMO+1) of the first organic molecule OM1 are further increased by U eV (time 4). The increase in the (LUMO+1) generates an energy difference between the (LUMO+1) and the Fermi level of the write electrode 18. Accordingly, a third electron is not injected into the (LUMO+1) from the write electrode 18.

Then, application of the second write voltage Vwrite2 to the write electrode 18 is stopped (time 5). Then, after a certain amount of time, the electrons of the (LUMO+1) move to the LUMO and stabilize. Through the above process, the data 2 is written into the first organic molecule OM1. After the data 2 is written into the first organic molecule OM1, the LUMO and the (LUMO+1) of the first organic molecule OM1 are in a state of having higher energy than the data 0 by 2U eV.

As described above, writing the data 1 into the organic molecule OM requires applying the first write voltage Vwrite1 to the organic molecule OM. Writing the data 2 into the organic molecule OM requires applying the first write voltage Vwrite1 to the organic molecule OM and then applying the second write voltage Vwrite2 having a greater absolute value than the first write voltage Vwrite1 to the organic molecule OM.

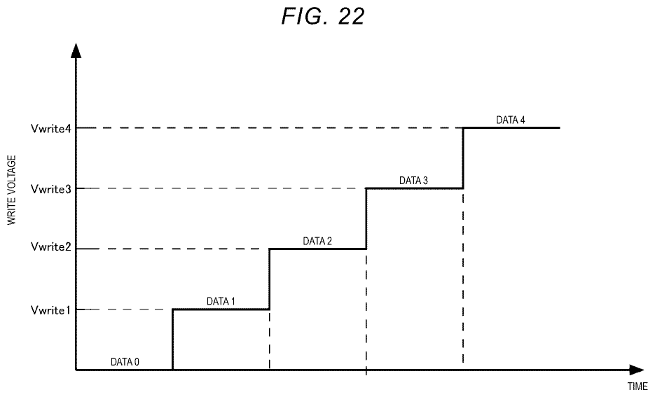

FIG. 22 is a view illustrating the write operation for the organic molecule OM. In FIG. 22, the horizontal axis denotes time, and the vertical axis denotes a level of the write voltage. The vertical axis denotes an absolute value of the write voltage.

As illustrated in FIG. 22, in writing the data 1 into the organic molecule OM, the first write voltage Vwrite1 is applied to the organic molecule OM. In writing the data 2 into the organic molecule OM, the first write voltage Vwrite1 is applied to the organic molecule OM, and then the second write voltage Vwrite2 having a greater absolute value than the first write voltage Vwrite1 is applied. In writing the data 3 into the organic molecule OM, the first write voltage Vwrite1 and the second write voltage Vwrite2 are applied to the organic molecule OM, and then a third write voltage Vwrite3 having a greater absolute value than the second write voltage Vwrite2 is applied. In writing the data 4 into the organic molecule OM, the first write voltage Vwrite1, the second write voltage Vwrite2, and the third write voltage Vwrite3 are applied to the organic molecule OM, and then a fourth write voltage Vwrite4 having a greater absolute value than the third write voltage Vwrite3 is applied.

As illustrated in FIG. 22, in the organic molecular memory 100, in writing data into the organic molecule OM, the write voltage Vwrite of a different level is used depending on a value of the data to be written. For example, in the organic molecular memory 100, in writing data into the organic molecule OM, the write voltage Vwrite of a different level is applied between the lower electrode 12 and the write electrode 18 depending on the value of the data to be written.

As illustrated in FIG. 22, in the organic molecular memory 100, in writing data into the organic molecule OM, a plurality of write voltages Vwrite of different levels are applied in a stepwise manner between the lower electrode 12 and the write electrode 18.

For example, the write operation of data into the organic molecule OM is controlled by the write control circuit 102.

When injection of the electrons into the (LUMO+1) from the write electrode 18 is completed in a very short time, the write voltage Vwrite does not necessarily have to be applied in a stepwise or step-like manner as illustrated in FIG. 22. For example, in writing the data 4 into the organic molecule OM, the voltage applied to the organic molecule OM may be continuously increased from 0 V to the fourth write voltage Vwrite4.

For example, in writing the data 1 into the first organic molecule OM1, the second voltage V2 is 0 V, and the third voltage V3 is 0 V.

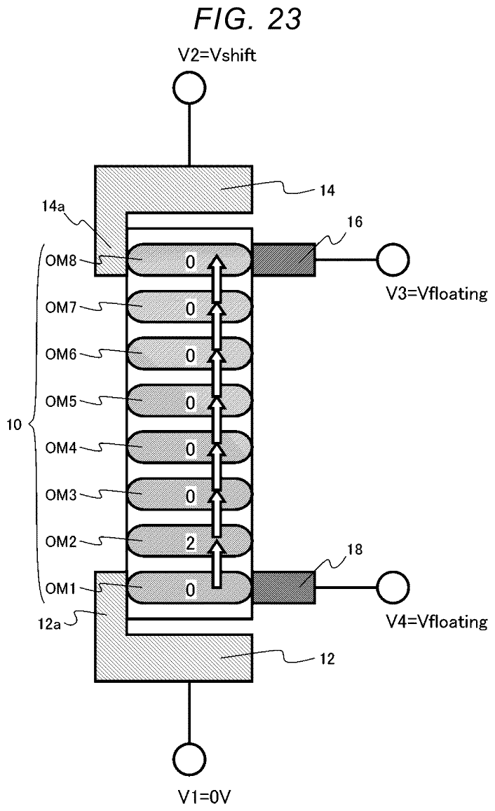

After the data 2 is written into the first organic molecule OM1, the data of the organic molecule OM is transmitted in a direction from the lower electrode 12 to the upper electrode 14 as illustrated in FIG. 23. The data 2 of the first organic molecule OM1 is transmitted to the second organic molecule OM2.

For example, in transmitting the data of the organic molecule OM, the first voltage V1 is set to 0 V, and the second voltage V2 is set to a shift voltage Vshift. The shift voltage Vshift is applied between the upper electrode 14 and the lower electrode 12. The shift voltage Vshift is a positive voltage.

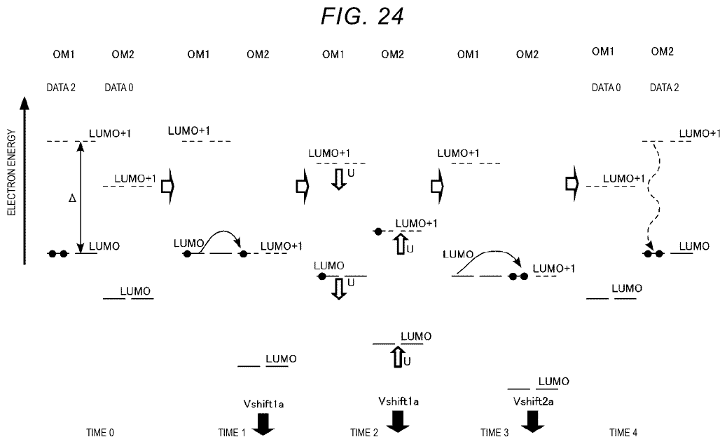

FIG. 24 is a view illustrating a transmission operation of data from the first organic molecule OM1 to the second organic molecule OM2. FIG. 24 is a view illustrating transmission of the data 2 from the first organic molecule OM1 to the second organic molecule OM2. That is, FIG. 24 is a view illustrating transmission of two electrons from the first organic molecule OM1 to the second organic molecule OM2. FIG. 24 is a view illustrating temporal changes in the electronic state of the first organic molecule OM1 and in an electronic state of the second organic molecule OM2.

Before the data 2 is transmitted, data stored in the first organic molecule OM1 is the data 2. Data stored in the second organic molecule OM2 is the data 0 (time 0).

Next, a first shift voltage Vshift1 is applied to the upper electrode 14. The first shift voltage Vshift1 is a positive voltage. A shift voltage Vshift1a obtained by capacitively dividing the first shift voltage Vshift1 is applied between the second organic molecule OM2 and the first organic molecule OM1 (time 1).

By applying the first shift voltage Vshift1, the energy level of the second organic molecule OM2 is relatively decreased, and the LUMO of the first organic molecule OM1 and the (LUMO+1) of the second organic molecule OM2 are aligned with each other. By aligning the LUMO of the first organic molecule OM1 and the (LUMO+1) of the second organic molecule OM2 with each other, one electron is injected into the (LUMO+1) of the second organic molecule OM2 from the LUMO of the first organic molecule OM1 through tunneling.

When one electron is injected into the (LUMO+1) of the second organic molecule OM2, on-site Coulomb repulsion occurs, and the LUMO and (LUMO+1) of the second organic molecule OM2 are increased by U eV. Meanwhile, in the first organic molecule OM1, since one electron is removed, on-site Coulomb repulsion is reduced, and the LUMO and (LUMO+1) of the first organic molecule OM1 are decreased by U eV (time 2). An energy difference is generated between the LUMO of the first organic molecule OM1 and the (LUMO+1) of the second organic molecule OM2. Accordingly, the second electron is not injected into the second organic molecule OM2 from the first organic molecule OM1.

Next, a second shift voltage Vshift2 is applied to the upper electrode 14. The second shift voltage Vshift2 is a positive voltage. The second shift voltage Vshift2 is a voltage different from the first shift voltage Vshift1. The second shift voltage Vshift2 is a voltage having a greater absolute value than the first shift voltage Vshift1. A shift voltage Vshift2a obtained by capacitively dividing the second shift voltage Vshift2 is applied between the second organic molecule OM2 and the first organic molecule OM1 (time 3).

By applying the second shift voltage Vshift2, the energy level of the second organic molecule OM2 is relatively decreased, and the LUMO of the first organic molecule OM1 and the (LUMO+1) of the second organic molecule OM2 are aligned with each other. By aligning the LUMO of the first organic molecule OM1 and the (LUMO+1) of the second organic molecule OM2 with each other, the second electron is injected into the (LUMO+1) of the second organic molecule OM2 from the LUMO of the first organic molecule OM1 through tunneling.

When the second electron is injected into the (LUMO+1) of the second organic molecule OM2, on-site Coulomb repulsion occurs, and the LUMO and (LUMO+1) of the second organic molecule OM2 are increased by U eV. Meanwhile, in the first organic molecule OM1, since one electron is removed, on-site Coulomb repulsion is reduced, and the LUMO and (LUMO+1) of the first organic molecule OM1 are decreased by U eV. An energy difference is generated between the LUMO of the first organic molecule OM1 and the (LUMO+1) of the second organic molecule OM2.

Then, application of the second shift voltage Vshift2 to the upper electrode 14 is stopped (time 4). Then, after a certain amount of time, the two electrons of the (LUMO+1) of the second organic molecule OM2 move to the LUMO of the second organic molecule OM2 and stabilize. Through the above process, the data 2 is transmitted to the second organic molecule OM2 from the first organic molecule OM1.

As described above, transmitting the data 2 to the second organic molecule OM2 from the adjacent first organic molecule OM1 requires applying the first shift voltage Vshift1 and then applying the second shift voltage Vshift2 having a greater absolute value than the first shift voltage Vshift1.

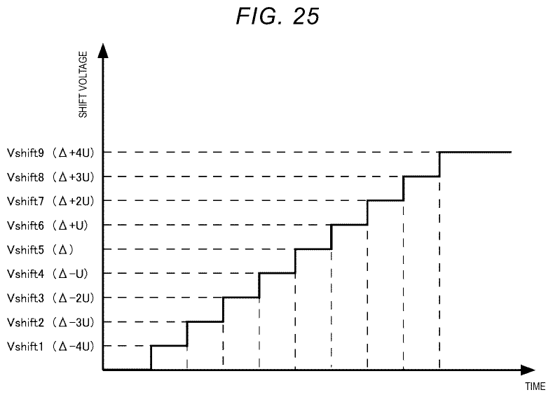

FIG. 25 is a view illustrating a shift operation of the data of the organic molecule OM. In FIG. 25, the horizontal axis denotes time, and the vertical axis denotes a level of the shift voltage. The vertical axis denotes an absolute value of the shift voltage.

For example, as illustrated in FIG. 25, in transmitting the data of the organic molecule OM, a plurality of shift voltages of different voltage levels are applied in a stepwise manner between the lower electrode 12 and the upper electrode 14. For example, as illustrated in FIG. 25, the first shift voltage Vshift1, the second shift voltage Vshift2, a third shift voltage Vshift3, a fourth shift voltage Vshift4, a fifth shift voltage Vshift5, a sixth shift voltage Vshift6, a seventh shift voltage Vshift7, an eighth shift voltage Vshift8, and a ninth shift voltage Vshift9 are applied in a stepwise manner.

For example, when the energy difference between the LUMO and the (LUMO+1) is Δ eV and an energy shift generated by on-site Coulomb repulsion of one electron is U eV, the first shift voltage Vshift1 is a voltage corresponding to (Δ−4U) eV as a voltage applied between adjacent organic molecules OM, the second shift voltage Vshift2 is a voltage corresponding to (Δ−3U) eV as a voltage applied between adjacent organic molecules OM, the third shift voltage Vshift3 is a voltage corresponding to (Δ−2U) eV as a voltage applied between adjacent organic molecules OM, the fourth shift voltage Vshift4 is a voltage corresponding to (Δ−U) eV as a voltage applied between adjacent organic molecules OM, the fifth shift voltage Vshift5 is a voltage corresponding to Δ eV as a voltage applied between adjacent organic molecules OM, the sixth shift voltage Vshift6 is a voltage corresponding to (Δ+U) eV as a voltage applied between adjacent organic molecules OM, the seventh shift voltage Vshift7 is a voltage corresponding to (Δ+2U) eV as a voltage applied between adjacent organic molecules OM, the eighth shift voltage Vshift8 is a voltage corresponding to (Δ+3U) eV as a voltage applied between adjacent organic molecules OM, and the ninth shift voltage Vshift9 is a voltage corresponding to (Δ+4U) eV as a voltage applied between adjacent organic molecules OM.

That is, in transmitting data, the shift voltage Vshift corresponding to all possible energy differences between the LUMO and the (LUMO+1) between adjacent organic molecules OM is applied in a stepwise manner from the shift voltage Vshift having a smaller absolute value to the shift voltage Vshift having a greater absolute value. Through the shift operation, all electrons stored in all organic molecules OM in the organic molecule layer 10 can be transmitted to adjacent organic molecules OM.

For example, the shift operation of the data of the organic molecule OM is controlled by the shift control circuit 104.

When injection of the electrons into the (LUMO+1) of the organic molecule OM from the LUMO of the adjacent organic molecule OM is completed in a very short time, the shift voltage Vshift does not necessarily have to be applied in a stepwise or step-like manner as illustrated in FIG. 25. For example, the shift voltage Vshift may be continuously increased from 0 V to the ninth shift voltage Vshift9.

For example, in transmitting the data of the organic molecule OM, the read electrode 16 and the write electrode 18 are set to floating potentials. Hereinafter, for convenience of description, a state where the read electrode 16 and the write electrode 18 are set to floating potentials will be referred to as a state where the third voltage V3 and the fourth voltage V4 are floating voltages Vfloating.

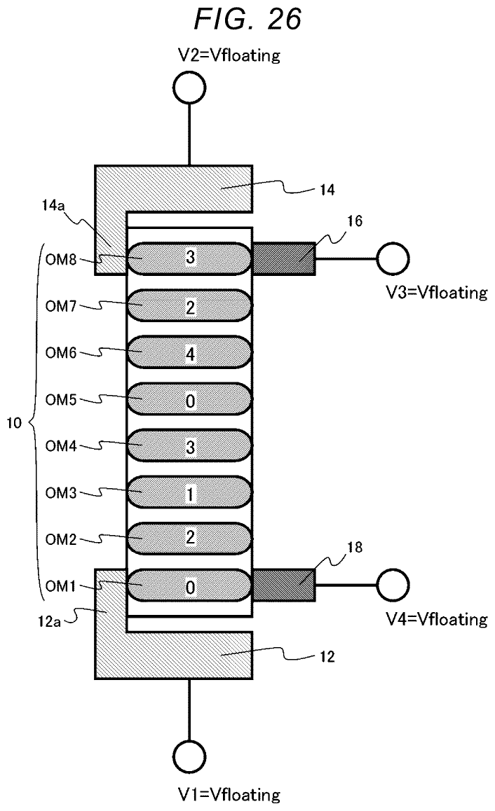

For example, by repeating writing of data into the first organic molecule OM1 and transmission of the data of the organic molecule OM, the data 0 to the data 4 are stored in all organic molecules OM as illustrated in FIG. 26. For example, the data stored in the organic molecule OM is stored by maintaining the first voltage V1, the second voltage V2, the third voltage V3, and the fourth voltage V4 at the floating voltage Vfloating. In other words, the organic molecular memory 100 functions as a non-volatile memory capable of storing data even in a state where a power supply voltage is not applied.

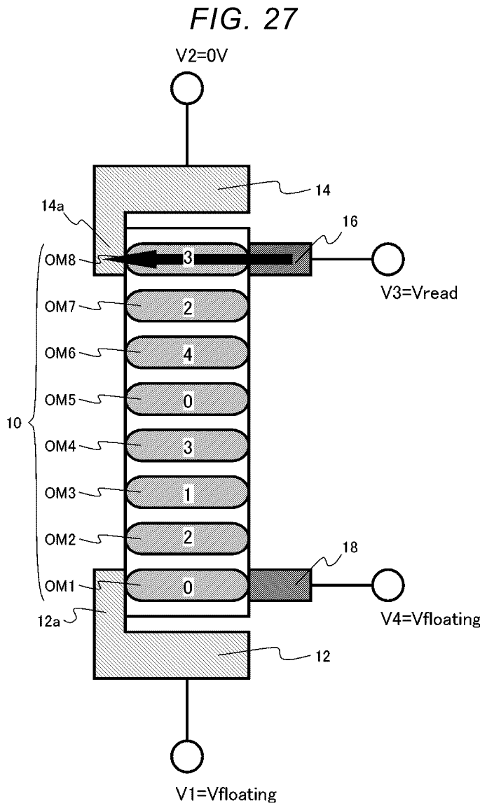

Next, as illustrated in FIG. 27, data of the eighth organic molecule OM8 is read. For example, in reading the data of the eighth organic molecule OM8, the second voltage is set to 0 V, and the third voltage is set to a read voltage Vread. For example, the read voltage Vread is a positive voltage. For example, an absolute value of the read voltage Vread is smaller than an absolute value of the write voltage Vwrite.

A current flows into the second part 14a from the read electrode 16 through the eighth organic molecule OM8. A level of the current flowing in the eighth organic molecule OM8 changes depending on the data stored in the eighth organic molecule OM8. For example, when the data stored in the eighth organic molecule OM8 is the data 3, a large current flows compared to the current when the data stored in the eighth organic molecule OM8 is the data 0, the data 1, or the data 2. This results from a change in conductance of the eighth organic molecule OM8 caused by the number of electrons stored in the eighth organic molecule OM8.

For example, the current flowing from the read electrode 16 to the upper electrode 14 flows into the first bit line BL1 through the upper select gate transistor TST in the ON state. The data of the eighth organic molecule OM8 is read based on the current flowing in the first bit line BL1.

The organic molecular memory 100 reads the data stored in the organic molecule OM by detecting the current flowing from the read electrode 16 to the upper electrode 14. The current flowing from the read electrode 16 to the upper electrode 14 is a tunneling current through a wave function of the organic molecule OM.

For example, in reading the data of the eighth organic molecule OM8, the first voltage V1 and the fourth voltage V4 are the floating voltages Vfloating.

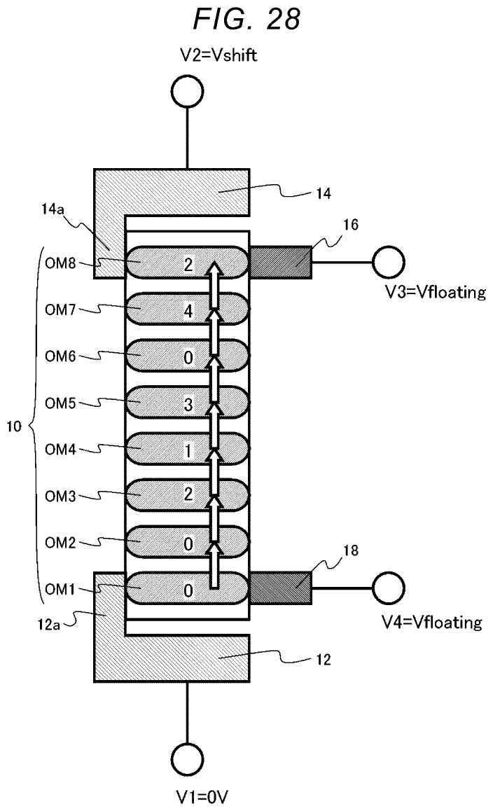

After the data of the eighth organic molecule OM8 is read, the data of the organic molecule OM is transmitted in a direction from the lower electrode 12 to the upper electrode 14 as illustrated in FIG. 28. For example, in transmitting the data of the organic molecule OM, the first voltage V1 is set to 0 V, and the second voltage V2 is set to the shift voltage Vshift. The shift voltage Vshift is a positive voltage. The third voltage V3 and the fourth voltage V4 are the floating voltages Vfloating.

For example, an erasing operation of the data of the eighth organic molecule OM8 may be performed before transmitting the data of the organic molecule OM. For example, in erasing the data of the eighth organic molecule OM8, the second voltage V2 and the third voltage V3 are set to positive voltages. For example, by setting the second voltage V2 and the third voltage V3 to positive voltages, electrons are removed from the eighth organic molecule OM8 even when the data 3 is stored in the eighth organic molecule OM8. Accordingly, the data of the eighth organic molecule OM8 can be reset to the data 0.

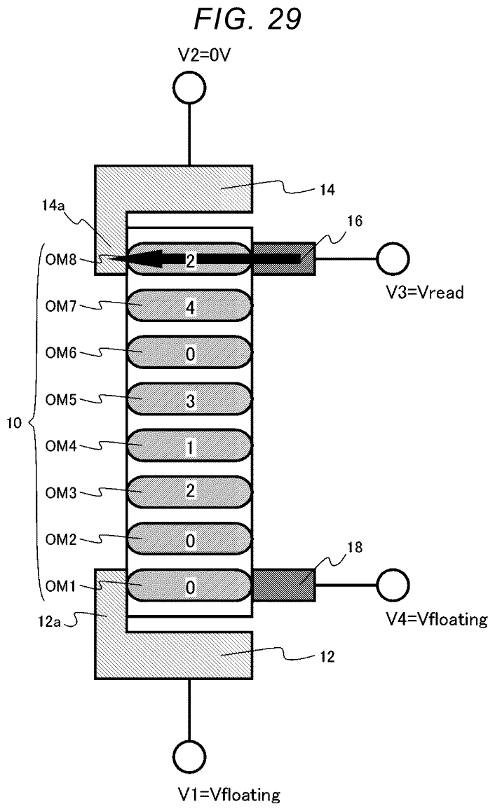

Next, as illustrated in FIG. 29, the data of the eighth organic molecule OM8 is read. The data of the eighth organic molecule OM8 is data stored in the seventh organic molecule OM7 before the data is transmitted. For example, in reading the data of the eighth organic molecule OM8, the second voltage is set to 0 V, and the third voltage is set to the read voltage Vread. For example, the first voltage V1 and the fourth voltage V4 are the floating voltages Vfloating.

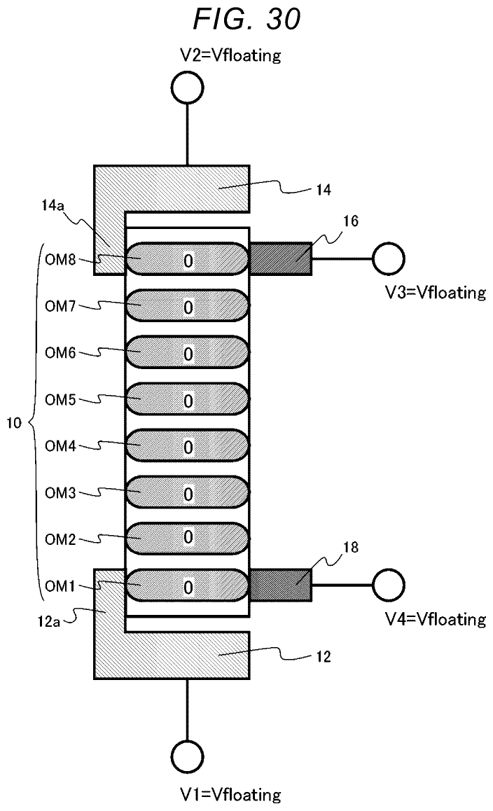

By repeating reading of the data of the eighth organic molecule OM8 and transmission of the data of the organic molecule OM, the data stored in all organic molecules OM of the organic molecule layer 10 can be read. After the data stored in all organic molecules OM is read, the organic molecule layer 10 returns to the initial state as illustrated in FIG. 30.

Next, an action and an effect of the organic molecular memory 100 according to the first embodiment will be described.

Implementation of a large capacity and a low cost of the non-volatile memory is desired. The organic molecular memory 100 according to the first embodiment uses an organic molecule as a memory cell. Use of a micro-sized organic molecule as a memory cell can achieve a micro-sized memory cell. The memory cell array 101 is provided with a three-dimensional structure by arranging the plurality of organic molecules OM in one direction in a self-aligned manner. For example, since the organic molecules OM are arranged in one direction to perform the shift register operation, a control electrode for controlling individual memory cells is not required.

The organic molecule OM of the organic molecular memory 100 has a degenerate energy level. Accordingly, the organic molecule OM can store three or more charges at the same energy level. Thus, the organic molecular memory 100 including the organic molecule OM functions as a multivalued memory capable of storing multiple values in one memory cell.

The organic molecular memory 100 further performs the write operation of data using a change in energy level caused by on-site Coulomb repulsion. In the write operation, each electron can be distinctively injected into the organic molecule OM using different write voltages Vwrite. Accordingly, unintended injection of electrons into the organic molecule OM is prevented. Thus, erroneous writing of data into the organic molecule OM is prevented. For example, since erroneous writing of data is prevented, a verification operation of data is not required.

By providing the above configuration, the organic molecular memory 100 according to the first embodiment can implement a multivalued memory. Accordingly, a large capacity and a low cost of the organic molecular memory can be implemented.

The organic molecule OM preferably includes an alkyl chain having a carbon number of 3 or more as a side chain, and more preferably includes an alkyl chain having a carbon number of 4 or more. By including an alkyl chain as a side chain, the plurality of organic molecules OM are easily arranged in a self-aligned manner with each other in the first direction.

In particular, when the organic molecule OM is a metal complex and includes a plane formed by atoms of an annular structure, planes formed by the atoms of the annular structures of the organic molecules OM are easily arranged in a self-aligned manner to face each other in the first direction.

The organic molecule OM is preferably a liquid crystal molecule. When the organic molecule OM is a liquid crystal molecule, the plurality of organic molecules OM are easily arranged in a self-aligned manner with each other in the first direction.

The organic molecule OM is preferably positioned between the first part 12a of the lower electrode and the write electrode 18 in a direction intersecting with the first direction. The organic molecule OM is preferably positioned between the first part 12a and the write electrode 18 in a direction orthogonal to the first direction. The above configuration stabilizes the write operation of multivalued data of the organic molecule OM.

The organic molecule OM is preferably positioned between the second part 14a of the upper electrode 14 and the read electrode 16 in a direction intersecting with the first direction. The organic molecule OM is preferably positioned between the second part 14a and the read electrode 16 in a direction orthogonal to the first direction. The above configuration stabilizes the read operation of the multivalued data of the organic molecule OM.

### Modification Example

An organic molecular memory 100 according to a modification example is different from the organic molecular memory 100 according to the first embodiment in that the lower electrode does not include the first part 12a and the upper electrode does not include the second part 14a.

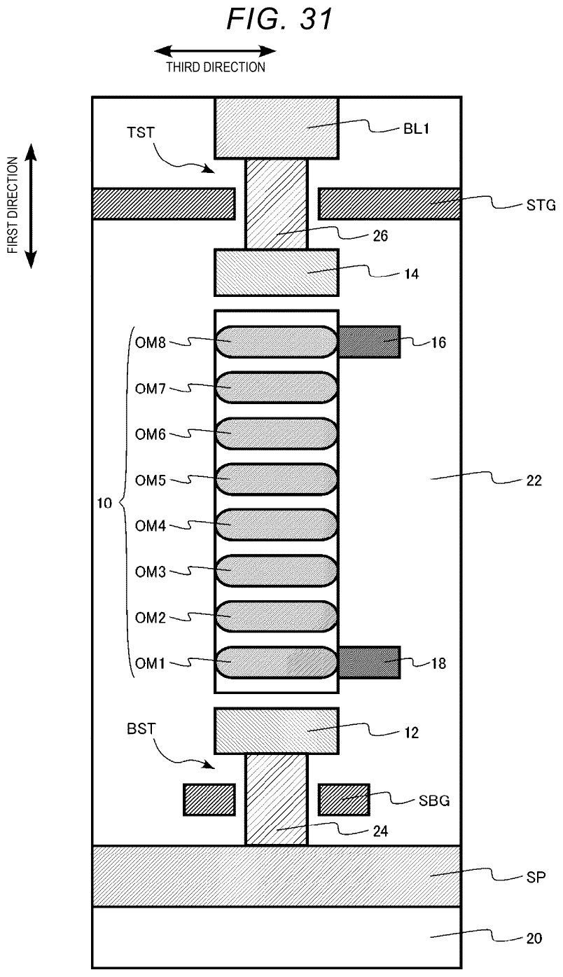

FIG. 31 is a schematic cross-sectional view of the organic molecular memory 100 according to the modification example of the first embodiment. FIG. 31 is a view corresponding to FIG. 3 of the first embodiment.

As illustrated in FIG. 31, the lower electrode 12 does not include the first part 12a in the lower electrode 12 of the organic molecular memory 100 according to the first embodiment. The upper electrode 14 does not include the second part 14a in the upper electrode 14 of the organic molecular memory 100 according to the first embodiment.

The organic molecular memory 100 according to the modification example can implement a large capacity and a low cost of the non-volatile memory, like the organic molecular memory 100 according to the first embodiment.

### Second Embodiment

A non-volatile organic molecular memory 200 according to a second embodiment is different from the organic molecular memory 100 according to the first embodiment in terms of not including the write electrode 18. Hereinafter, duplicate content of the first embodiment may not be described in full.

In the non-volatile organic molecular memory 200, memory cells are three-dimensionally disposed, and, the memory cells store data using charges in organic molecules. The organic molecular memory 200 performs a shift register operation.

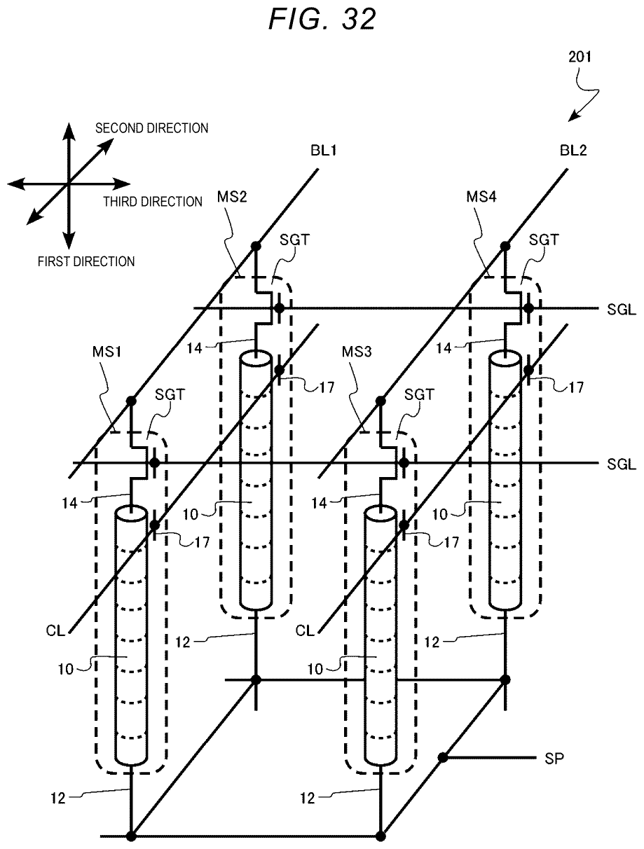

FIG. 32 is an equivalent circuit diagram of a memory cell array 201 of the organic molecular memory 200 according to the second embodiment.

As illustrated in FIG. 32, the memory cell array 201 includes the first memory string MS1, the second memory string MS2, the third memory string MS3, the fourth memory string MS4, the source plate SP, a select gate line SGL, a common line CL, the first bit line BL1, and the second bit line BL2.

Hereinafter, the first memory string MS1, the second memory string MS2, the third memory string MS3, and the fourth memory string MS4 may be individually or collectively referred to as the memory string MS. The first bit line BL1 and the second bit line BL2 may be individually or collectively referred to as the bit line BL.

Each of the first memory string MS1, the second memory string MS2, the third memory string MS3, and the fourth memory string MS4 includes the organic molecule layer 10, the lower electrode 12, the upper electrode 14, a common electrode 17, and a select gate transistor SGT.

In the memory cell array 201, a direction from the lower electrode 12 to the upper electrode 14 is defined as the first direction. A direction intersecting with the first direction is defined as the second direction. A direction intersecting with the first direction and the second direction is defined as the third direction. For example, the second direction is perpendicular to the first direction. For example, the third direction is perpendicular to the first direction and the second direction.

As illustrated in FIG. 32, the first memory string MS1, the second memory string MS2, the third memory string MS3, and the fourth memory string MS4 extend in the first direction.

The first bit line BL1 and the second bit line BL2 extend in the second direction. The first memory string MS1 and the second memory string MS2 are provided between the first bit line BL1 and the source plate SP. The third memory string MS3 and the fourth memory string MS4 are provided between the second bit line BL2 and the source plate SP.

The first bit line BL1 is above the first memory string MS1 and the second memory string MS2 in the first direction. The second bit line BL2 is above the third memory string MS3 and the fourth memory string MS4 in the first direction. The second bit line BL2 is electrically separated from the first bit line BL1.

The organic molecule layer 10 includes a plurality of organic molecules. Each of the plurality of organic molecules functions as a memory cell.

The select gate transistor SGT is provided between the upper electrode 14 and the first bit line BL1 or between the upper electrode 14 and the second bit line BL2. The select gate line SGL extends in the third direction.

The select gate transistor SGT is controlled to enter an ON state or an OFF state by a gate voltage applied to the select gate line SGL. The select gate transistor SGT has a function of selecting a desired memory string MS from a plurality of memory strings MS.

The common line CL extends in the second direction. The common line CL is connected to the common electrode 17. Data is written to the organic molecules facing the common electrode 17 by a write voltage applied to the common line CL. Data of the organic molecules facing the common electrode 17 is read by detecting a current flowing between the common electrode 17 and the upper electrode 14.

For example, the common electrode 17 of the first memory string MS1 and the common electrode 17 of the second memory string MS2 are electrically connected to each other by the common line CL. For example, the common electrode 17 of the third memory string MS3 and the common electrode 17 of the fourth memory string MS4 are electrically connected to each other by the common line CL.

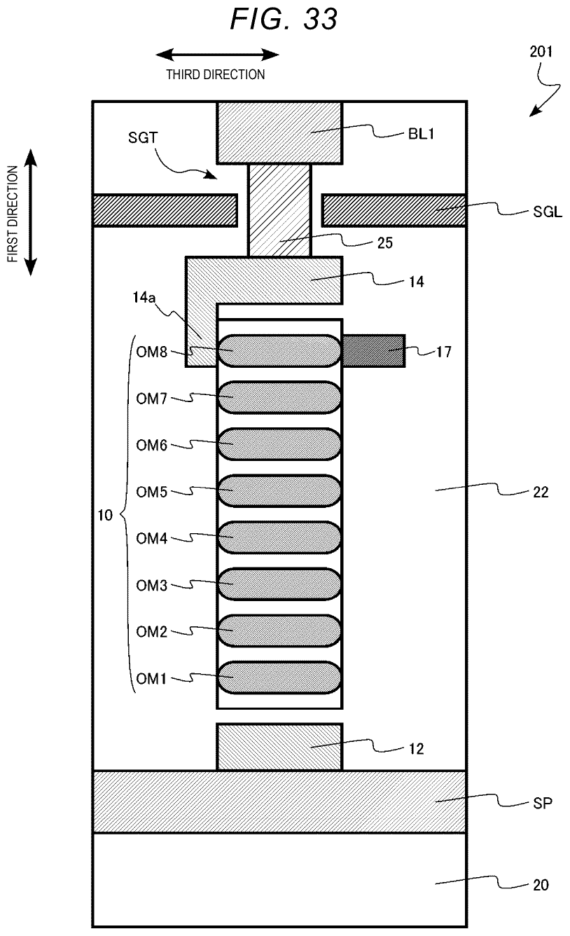

FIG. 33 is a schematic cross-sectional view of the organic molecular memory according to the second embodiment. FIG. 33 is a cross-sectional view of the memory cell array 201. FIG. 33 is a cross-sectional view parallel to the first direction and the third direction. FIG. 33 is a cross section including the first memory string MS1.

The memory cell array 201 includes the organic molecule layer 10, the lower electrode 12, the upper electrode 14, the common electrode 17, the substrate insulating layer 20, the interlayer insulating layer 22, the source plate SP, the first bit line BL1, and the select gate transistor SGT.

The organic molecule layer 10 includes the first organic molecule OM1, the second organic molecule OM2, the third organic molecule OM3, the fourth organic molecule OM4, the fifth organic molecule OM5, the sixth organic molecule OM6, the seventh organic molecule OM7, and the eighth organic molecule OM8.

Hereinafter, the first organic molecule OM1, the second organic molecule OM2, the third organic molecule OM3, the fourth organic molecule OM4, the fifth organic molecule OM5, the sixth organic molecule OM6, the seventh organic molecule OM7, and the eighth organic molecule OM8 may be individually or collectively referred to as the organic molecule OM.

For example, the substrate insulating layer 20 is made of an oxide. For example, the substrate insulating layer 20 is made of a silicon oxide.

The source plate SP is provided on the substrate insulating layer 20. The source plate SP is made of a conductor. For example, the source plate SP is made of a metal or a semiconductor. For example, the source plate SP is made of tungsten.

The lower electrode 12 is provided between the source plate SP and the organic molecule layer 10.

The lower electrode 12 is electrically connected to the source plate SP. For example, the lower electrode 12 is in contact with the source plate SP.

The lower electrode 12 is made of a conductor. For example, the lower electrode 12 is made of a metal or a semiconductor. For example, the lower electrode 12 is made of tungsten.

The organic molecule layer 10 is provided between the lower electrode 12 and the upper electrode 14. The organic molecule layer 10 extends in the first direction from the lower electrode 12 to the upper electrode 14.

The first organic molecule OM1, the second organic molecule OM2, the third organic molecule OM3, the fourth organic molecule OM4, the fifth organic molecule OM5, the sixth organic molecule OM6, the seventh organic molecule OM7, and the eighth organic molecule OM8 are stacked in the first direction.

The upper electrode 14 is provided on the organic molecule layer 10. The upper electrode 14 is provided between the organic molecule layer 10 and the first bit line BL1.

The second part 14a of the upper electrode 14 faces the eighth organic molecule OM8 in the third direction. The eighth organic molecule OM8 is provided between the second part 14a and the common electrode 17. The eighth organic molecule OM8 is positioned between the second part 14a and the common electrode 17 in the third direction.

The upper electrode 14 is made of a conductor. For example, the upper electrode 14 is made of a metal or a semiconductor. For example, the upper electrode 14 is made of tungsten.

The common electrode 17 faces the eighth organic molecule OM8 in the third direction. For example, a distance between the common electrode 17 and the eighth organic molecule OM8 is smaller than the length of the eighth organic molecule OM8 in the third direction. For example, the distance between the common electrode 17 and the eighth organic molecule OM8 is smaller than the disposition pitch of the organic molecules OM in the first direction.

The common electrode 17 has a function of injecting charges into the eighth organic molecule OM8. For example, the common electrode 17 has a function of injecting electrons into the eighth organic molecule OM8.

The common electrode 17 has a function of causing a current to flow into the eighth organic molecule OM8. The common electrode 17 as one terminal and the upper electrode 14 as the other terminal cause the current to flow into the eighth organic molecule OM8.

The common electrode 17 is made of a conductor. For example, the common electrode 17 is made of a metal or a semiconductor. For example, the common electrode 17 is made of tungsten.

The select gate transistor SGT includes a semiconductor layer 25. The semiconductor layer 25 is provided between the upper electrode 14 and the first bit line BL1. For example, the semiconductor layer 25 is in contact with the upper electrode 14 and the first bit line BL1.

When the select gate transistor SGT enters the ON state, a channel is formed in the semiconductor layer 25. For example, the semiconductor layer 25 is polycrystalline silicon.

The upper electrode 14 functions as a source and drain region of the select gate transistor SGT. A part of the first bit line BL1 functions as the source and drain region of the select gate transistor SGT.

A part of the select gate line SGL functions as a gate electrode of the select gate transistor SGT. A gate insulating film (not illustrated) is provided between the part of the select gate line SGL and the semiconductor layer 25.

The select gate line SGL is made of a conductor. For example, the select gate line SGL is made of a metal. For example, the select gate line SGL is made of tungsten.

The first bit line BL1 is made of a conductor. For example, the first bit line BL1 is made of a metal. For example, the first bit line BL1 is made of tungsten.

For example, the interlayer insulating layer 22 is made of an oxide. For example, the interlayer insulating layer 22 is made of a silicon oxide.

Next, an operation of the organic molecular memory 200 will be described.

During a write operation and a read operation, the organic molecular memory 200 sequentially transmits data stored in a plurality of organic molecules OM stacked in the organic molecule layer 10 to adjacent organic molecules OM. The organic molecular memory 200 performs a so-called shift register operation during the write operation and the read operation.

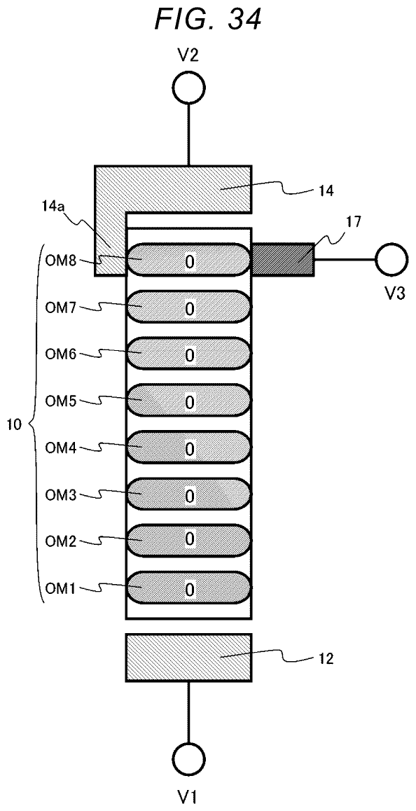

FIGS. 34, 35, 36, 37, 38, 39, 40, and 41 are views illustrating an operation of the organic molecular memory 200 according to the second embodiment.

FIG. 34 illustrates an initial state of the operation of the organic molecular memory 200. In the operation of the organic molecular memory 200, the first voltage V1, the second voltage V2, and the third voltage V3 are applied to the lower electrode 12, the upper electrode 14, and the common electrode 17, respectively.

As illustrated in FIG. 34, as the initial state of the operation of the organic molecular memory 200, data stored in all organic molecules OM is considered to be the data 0.

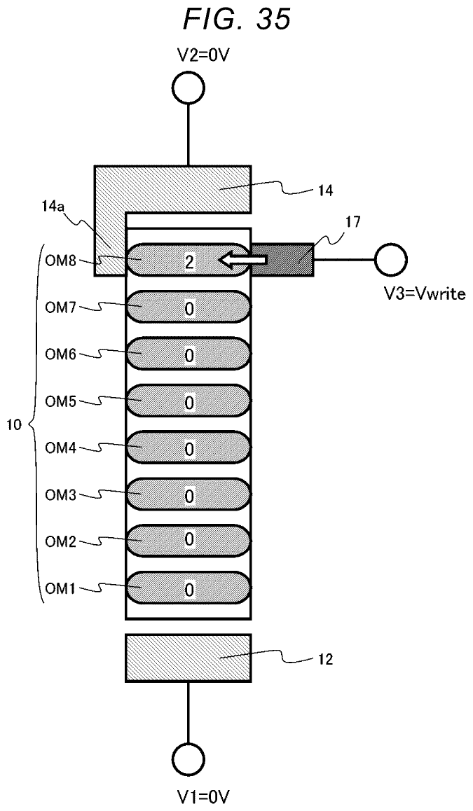

First, for example, as illustrated in FIG. 35, the data 2 is written into the eighth organic molecule OM8. In writing the data 2 into the eighth organic molecule OM8, the third voltage V3 is set to a voltage lower than the second voltage V2. For example, in writing the data 2 into the eighth organic molecule OM8, the second voltage V2 is set to 0 V, and the third voltage V3 is set to the write voltage Vwrite. The write voltage Vwrite is a negative voltage.

Electrons are injected into the eighth organic molecule OM8 from the common electrode 17, and the data 2 is written into the eighth organic molecule OM8.

For example, in writing the data 2 into the eighth organic molecule OM8, the first voltage V1 is 0 V.

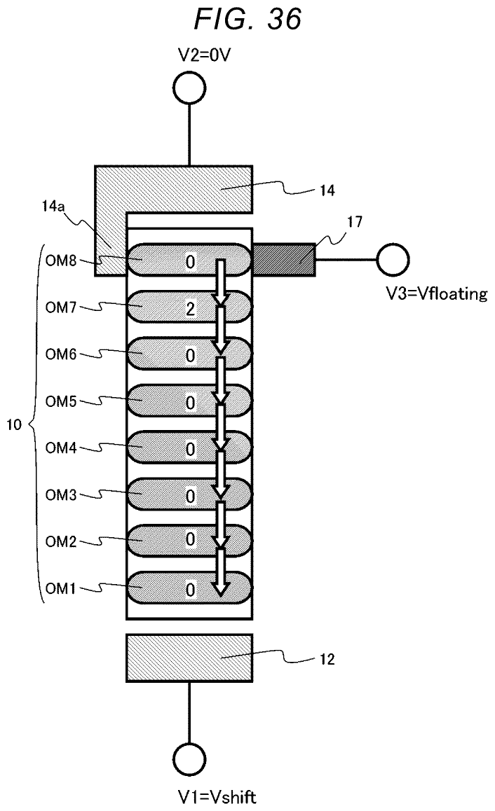

After the data 2 is written into the eighth organic molecule OM8, the data of the organic molecule OM is transmitted in a direction from the upper electrode 14 to the lower electrode 12 as illustrated in FIG. 36. For example, in transmitting the data of the organic molecule OM, the second voltage V2 is set to 0 V, and the first voltage V1 is set to the shift voltage Vshift. The shift voltage Vshift is a positive voltage.

For example, in transmitting the data of the organic molecule OM, the common electrode 17 is set to a floating potential. Hereinafter, for convenience of description, a state where the common electrode 17 is set to a floating potential will be referred to as a state where the third voltage V3 is the floating voltage Vfloating.

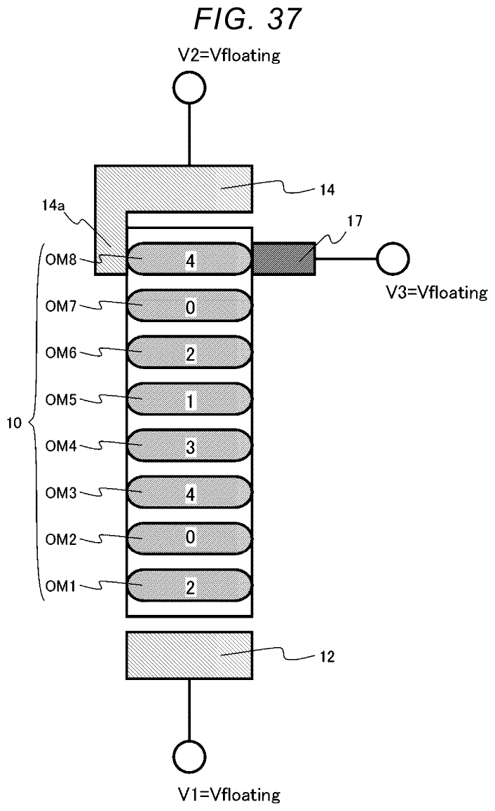

For example, by repeating writing of data into the eighth organic molecule OM8 and transmission of the data of the organic molecule OM, the data 0 to the data 4 are stored in all organic molecules OM as illustrated in FIG. 37. For example, the data stored in the organic molecule OM is stored by maintaining the first voltage V1, the second voltage V2, and the third voltage V3 at the floating voltage Vfloating. In other words, the organic molecular memory 200 functions as a non-volatile memory capable of storing data even in a state where a power supply voltage is not applied.

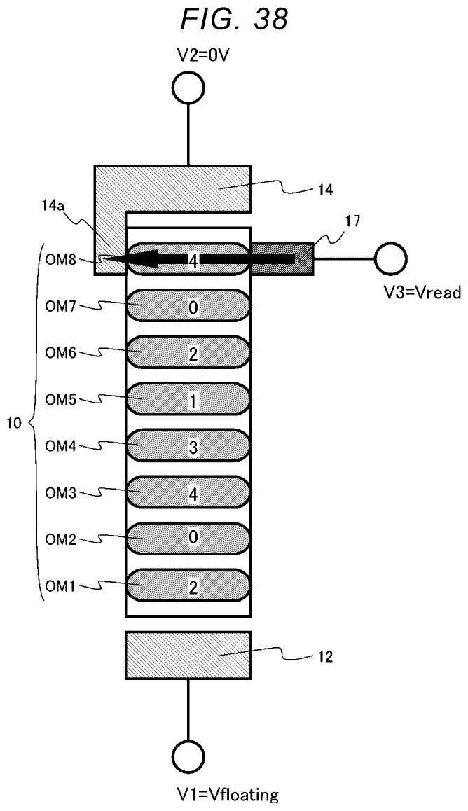

Next, as illustrated in FIG. 38, the data of the eighth organic molecule OM8 is read. For example, in reading the data of the eighth organic molecule OM8, the second voltage is set to 0 V, and the third voltage is set to the read voltage Vread. The read voltage Vread is a positive voltage. For example, the absolute value of the read voltage Vread is smaller than the absolute value of the write voltage Vwrite.

A current flows into the second part 14a of the upper electrode 14 from the common electrode 17 through the eighth organic molecule OM8. A level of the current flowing in the eighth organic molecule OM8 changes depending on the data stored in the eighth organic molecule OM8. For example, when the data stored in the eighth organic molecule OM8 is the data 4, a large current flows compared to the current when the data stored in the eighth organic molecule OM8 is the data 0, the data 1, the data 2, or the data 3.

For example, the current flowing from the common electrode 17 to the upper electrode 14 flows into the first bit line BL1 through the select gate transistor SGT in the ON state. The data of the eighth organic molecule OM8 is read based on the current flowing in the first bit line BL1.

The organic molecular memory 200 reads the data stored in the organic molecule OM by detecting the current flowing from the common electrode 17 to the upper electrode 14.

For example, in reading the data of the eighth organic molecule OM8, the first voltage V1 is the floating voltage Vfloating.

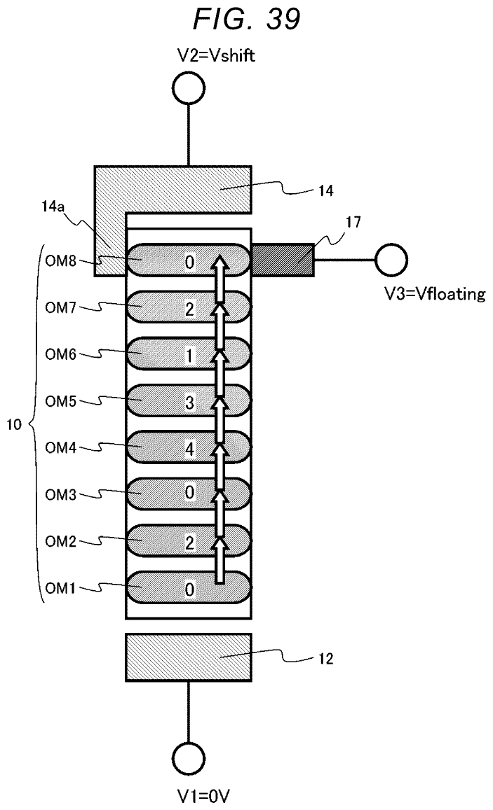

After the data of the eighth organic molecule OM8 is read, the data of the organic molecule OM is transmitted in a direction from the lower electrode 12 to the upper electrode 14 as illustrated in FIG. 39. For example, in transmitting the data of the organic molecule OM, the first voltage V1 is set to 0 V, and the second voltage V2 is set to the shift voltage Vshift. The shift voltage Vshift is a positive voltage. The third voltage V3 is the floating voltage Vfloating.

For example, an erasing operation of the data of the eighth organic molecule OM8 may be performed before transmitting the data of the organic molecule OM. For example, in erasing the data of the eighth organic molecule OM8, the second voltage V2 and the third voltage V3 are set to positive voltages. For example, by setting the second voltage V2 and the third voltage V3 to positive voltages, electrons are removed from the eighth organic molecule OM8 even when the data 1 is stored in the eighth organic molecule OM8. Accordingly, the data of the eighth organic molecule OM8 can be reset to the data 0.

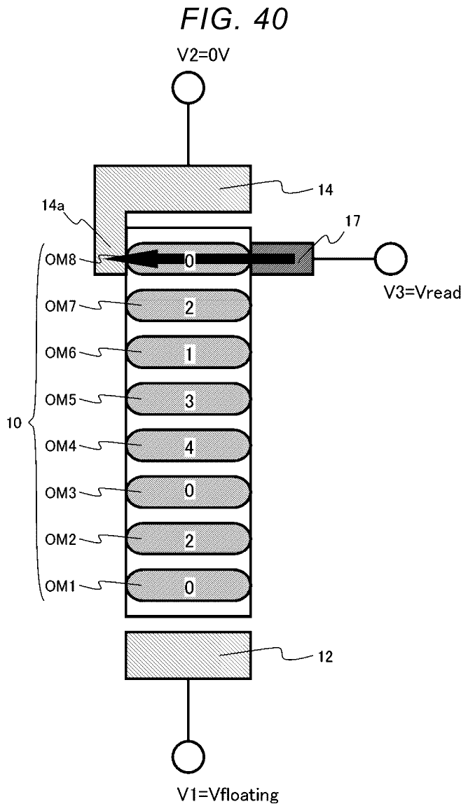

Next, as illustrated in FIG. 40, the data of the eighth organic molecule OM8 is read. The data of the eighth organic molecule OM8 is data stored in the seventh organic molecule OM7 before the data is transmitted. For example, in reading the data of the eighth organic molecule OM8, the second voltage is set to 0 V, and the third voltage is set to the read voltage Vread. For example, the first voltage V1 is the floating voltage Vfloating.

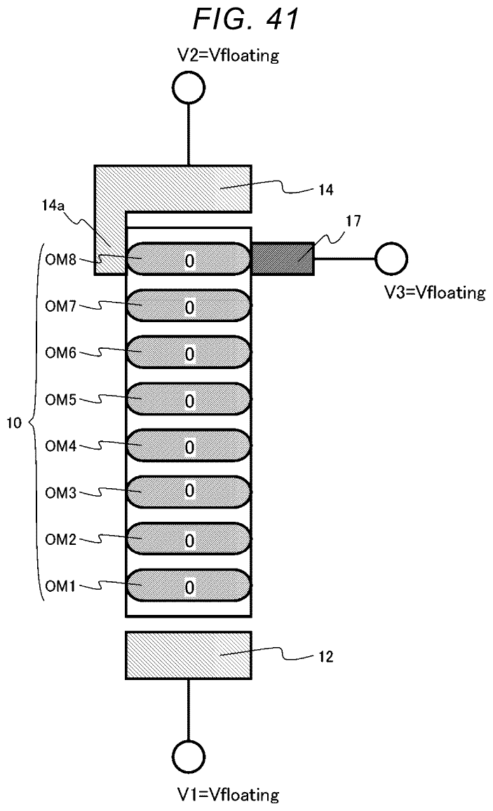

By repeating reading of the data of the eighth organic molecule OM8 and transmission of the data of the organic molecule OM, the data stored in all organic molecules OM of the organic molecule layer 10 can be read. After the data stored in all organic molecules OM is read, the organic molecule layer 10 returns to the initial state as illustrated in FIG. 41.

The organic molecular memory 200 according to the second embodiment can implement a large capacity and a low cost of the organic molecular memory, like the organic molecular memory 100 according to the first embodiment.

While the first and second embodiments describe an example in which the number of organic molecules OM in the organic molecule layer 10 is eight, the number of organic molecules OM is not limited to eight. The number of organic molecules OM may be any number greater than or equal to two.

While the first and second embodiments describe an example in which the number of memory strings MS is four, the number of memory strings MS is not limited to four. The number of memory strings MS may be any number greater than or equal to one.

While the first and second embodiments describe an example in which the charges stored in the organic molecule OM are electrons, the charges stored in the organic molecule OM may be electron holes.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An organic molecular memory comprising:
a first electrode;
a second electrode above the first electrode in a first direction;
an organic molecule layer between the first and second electrodes and including a first molecule and a second molecule, the second molecule being closer to the second electrode than the first molecule; and
a third electrode facing the second molecule, wherein
each of the first and second molecules includes a metal complex or a fullerene derivative.

2. The organic molecular memory according to claim 1, further comprising:
a fourth electrode, wherein
the first electrode further includes a first part,
the second electrode further includes a second part,
the first molecule is between the first part and the fourth electrode in a direction intersecting with the first direction, and
the second molecule is between the second part and the third electrode in a direction intersecting with the first direction.

3. The organic molecular memory according to claim 1, wherein
the first and second molecules have degenerate energy levels.

4. The organic molecular memory according to claim 1, wherein
the first and second molecules are liquid crystal molecules.

5. The organic molecular memory according to claim 1, wherein
each of the first and second molecules is a metal complex,
the first molecule has a first annular structure in which atoms are in a first plane, and
the second molecule has a second annular structure in which atoms are in a second plane that faces the first plane in the first direction.

6. The organic molecular memory according to claim 1, wherein
each of the first and second molecules is a double-decker complex including a side chain.

7. The organic molecular memory according to claim 6, wherein
the double-decker complex includes two phthalocyanine skeletons stacked on each other and includes one rare earth element selected from the group consisting of lanthanum, cerium, praseodymium, neodymium, samarium, europium, gadolinium, terbium, dysprosium, holmium, erbium, thulium, ytterbium, and lutetium.

8. The organic molecular memory according to claim 6, wherein
the side chain includes an alkyl chain having a carbon number of 3 or more.

9. The organic molecular memory according to claim 1, wherein
each of the first and second molecules is a metallocene derivative including a side chain, a metalloporphyrin derivative including a side chain, or a metallophthalocyanine derivative including a side chain, and includes one metal element selected from the group consisting of iron, copper, cobalt, titanium, nickel, zinc, and chromium.

10. The organic molecular memory according to claim 9, wherein
the side chain includes an alkyl chain having a carbon number of 3 or more.

11. The organic molecular memory according to claim 1, wherein
each of the first and second molecules includes a fullerene derivative including a side chain.

12. The organic molecular memory according to claim 11, wherein
the side chain includes an alkyl chain having a carbon number of 3 or more.

13. The organic molecular memory according to claim 1, further comprising:
a fourth electrode facing the first molecule; and
a first control circuit, wherein
the first molecule is between a part of the first electrode and the fourth electrode in a direction intersecting with the first direction,
the second molecule is between a part of the second electrode and the third electrode in a direction intersecting with the first direction, and
the first control circuit is configured to, in writing data into the first molecule, apply a write voltage of a different voltage level between the first and fourth electrodes depending on a value of the data.

14. The organic molecular memory according to claim 1, further comprising:
a fourth electrode facing the first molecule; and
a first control circuit, wherein
the first molecule is between a part of the first electrode and the fourth electrode in a direction intersecting with the first direction,
the second molecule is between a part of the second electrode and the third electrode in a direction intersecting with the first direction, and
the first control circuit is configured to, in writing data into the first molecule, apply a plurality of write voltages of different voltage levels in a stepwise manner between the first and fourth electrodes.

15. The organic molecular memory according to claim 1, further comprising:
a second control circuit configured to, in transmitting data from the first molecule to the second molecule, apply a plurality of shift voltages of different voltage levels in a stepwise manner between the first and second electrodes.

16. An organic molecular memory comprising:
a first memory string extending in a first direction;
a second memory string extending in the first direction and adjacent to the first memory string in a second direction intersecting the first direction;
a third memory string extending in the first direction and adjacent to the first memory string in a third direction intersecting the first and second directions;
a first wire that extends in the second direction above the first and second memory strings; and
a second wire that extends in the second direction above the third memory string and is electrically separated from the first wire, wherein
each of the first, second, and third memory strings includes:
a first electrode,
a second electrode above the first electrode in the first direction,
an organic molecule layer between the first and second electrodes and including a first molecule and a second molecule, the second molecule being closer to the second electrode than the first molecule, and
a third electrode facing the second molecule, and
each of the first molecule and the second molecule includes a metal complex or a fullerene derivative.

17. The organic molecular memory according to claim 16, wherein
each of the first, second, and third memory strings further includes a fourth electrode,
the first electrode further includes a first part,
the second electrode further includes a second part,
the first molecule is between the first part and the fourth electrode in a direction intersecting with the first direction, and
the second molecule is between the second part and the third electrode in a direction intersecting with the first direction.

18. The organic molecular memory according to claim 16, wherein
the first and second molecules have degenerate energy levels.

19. The organic molecular memory according to claim 16, wherein
the first and second molecules are liquid crystal molecules.

20. The organic molecular memory according to claim 16, wherein
each of the first and second molecules is a metal complex,
the first molecule has a first annular structure in which atoms are in a first plane, and
the second molecule has a second annular structure in which atoms are in a second plane facing the first plane in the first direction.
